(19) United States
(12) Patent Application Publication
(10) Pub. No.: US 2025/0287821 A1
(43) Pub. Date: Sep. 11, 2025

(54) ELECTRONIC DEVICE

(71) Applicant: Samsung Display Co., LTD., Yongin-si (KR)

(72) Inventors: DONGHYUN SON, Yongin-si (KR); SEONGJUN LEE, Yongin-si (KR)

(21) Appl. No.: 19/057,439

(22) Filed: Feb. 19, 2025

(30) Foreign Application Priority Data
Mar. 6, 2024 (KR) 10-2024-0031713

(51) Int. Cl. H10K 59/80; H10K 59/122; H10K 59/126

(52) U.S. Cl. CPC H10K 59/8792; H10K 59/122; H10K 59/126

(57) ABSTRACT

An electronic device includes a display panel including a first area including a transmissive area, wherein the display panel includes a light shielding layer in which a plurality of openings, each defining the transmissive area, is defined in the first area, a plurality of light emitting elements, each of which includes a light emitting layer spaced apart from the opening, and a plurality of driving units, each of which is connected to a corresponding one of the light emitting elements, is spaced apart from the openings on a plane, and includes a transistor, each of the openings has one of N different shapes, the N shapes include one reference shape and N−1 tilted shapes, the tilted shapes correspond to shapes obtained by rotating the reference shape by predetermined tilt angles, and the tilt angles of the tilted shapes are different from each other.

This application claims priority to Korean Patent Application No. 10-2024-0031713, filed on Mar. 6, 2024, and all the benefits accruing therefrom under 35 U.S.C. § 119, the content of which in its entirety is herein incorporated by reference.

### BACKGROUND

### 1. Field

Embodiments of the disclosure described herein relate to an electronic device having improved captured image quality.

### 2. Description of the Related Art

An electronic device may include a device including various electronic components such as a display panel and an electronic module. The electronic module may include a camera, an infrared sensor, a proximity sensor or the like. The electronic module may be disposed below the display panel. Transmittance of a partial area of the display panel may be higher than transmittance of another partial area of the display panel. The electronic module may receive an external input through the partial area of the display panel having higher transmittance or provide an output through the partial area of the display panel having higher transmittance.

### SUMMARY

Embodiments of the disclosure provide an electronic device having improved captured image quality.

According to an embodiment, an electronic device includes a display panel including a first area including a transmissive area and a second area spaced apart from the transmissive area on a plane and adjacent to the first area, where the display panel includes a light shielding layer in which a plurality of first openings is defined in the first area, where each of the first openings defines the transmissive area, a plurality of light emitting elements, each of which includes a light emitting layer spaced apart from the first opening, and a plurality of driving units, each of which is connected to a corresponding one of the light emitting elements, is spaced apart from the first openings on a plane, and includes at least one transistor, each of the first openings has one of N different shapes, where N is a natural number greater than or equal to two, the N shapes include one reference shape and N−1 tilted shapes, the tilted shapes correspond to shapes obtained by rotating the reference shape by predetermined tilt angles, and the tilt angles of the tilted shapes are different from each other.

In an embodiment, a number of first openings arranged in the transmissive area is M, where N is a natural number greater than three and M is a natural number greater than N.

In an embodiment, the reference shape may not be a circular shape.

In an embodiment, the reference shape may have L vertices, where L is a natural number.

In an embodiment, one of the tilt angles may be greater than 360/N and less than 360/M.

In an embodiment, the reference shape may have a polygonal shape.

In an embodiment, the reference shape may have an irregular shape.

In an embodiment, a difference between the number of the first openings having a same shape and a number of the first openings having another same shape within the first area may be 1 or less.

In an embodiment, the display panel may further include a lower light shielding layer including a conductive material and overlapping the transistors, a pixel defining layer in which second openings are defined, where each of the second openings has a different shapes from the first openings and overlaps a corresponding one of the light emitting layers, and a black matrix in which third openings overlapping the second openings are defined, and the light shielding layer may include at least one selected from the lower light shielding layer, the pixel defining layer, and the black matrix.

In an embodiment, the light shielding layer may have a black color.

In an embodiment, the light shielding layer may include a light absorbing material.

In an embodiment, the electronic device may further include an electronic module overlapping the first area, where the electronic module may include a camera or an optical sensor.

In an embodiment, the light emitting layer of each of the light emitting elements in the first area may be spaced apart from the transmissive area and may overlap the light shielding layer.

In an embodiment, an area of the light emitting layer in the first area and an area of the light emitting layer in the second area may be different from each other.

In an embodiment, the tilted shapes may be arranged in a way such that the tilt angles thereof are increased in one direction.

In an embodiment, the tilted shapes may be arranged randomly.

According to an embodiment, an electronic device includes a display panel including a first area including a transmissive area and a second area spaced apart from the transmissive area on a plane and adjacent to the first area, where the display panel includes a light shielding layer in which a plurality of first openings is defined in the first area, where each of the first openings defines the transmissive area, a plurality of light emitting elements arranged in a plurality of second openings, respectively, where the second openings are different from the first openings, and a plurality of driving units, each of which is connected to a corresponding one of the light emitting elements, is spaced apart from the first openings on a plane, and includes at least one transistor, each of the first openings has one of N different shapes, where N is a natural number greater than or equal to two, the N shapes include one reference shape and N−1 tilted shapes, the reference shape corresponds to a shape having L vertices, where L is a natural number, and the tilted shapes correspond to shapes obtained by rotating the reference shape by predetermined tilt angles.

In an embodiment, the N shapes may have different tilt angles from each other, and one of the tilt angles may be 360/N or less.

In an embodiment, the N shapes may be arranged in a direction in which the tilt angles are increased in one direction.

In an embodiment, a difference between a number of the first openings having a same shape and a number of the first openings having another same shape within the first area may be 1 or less.

### BRIEF DESCRIPTION OF THE DRAWINGS

The above and other objects and features of embodiments of the disclosure will become apparent by describing in detail embodiments thereof with reference to the accompanying drawings.

FIGS. 1A to 1C are perspective views of an electronic device according to an embodiment of the disclosure.

FIG. 2A is an exploded perspective view of the electronic device according to an embodiment of the disclosure.

FIG. 2B is a block diagram of the electronic device according to an embodiment of the disclosure.

FIG. 3 is a cross-sectional view of a display device according to an embodiment of the disclosure.

FIG. 4 is a plan view of a display panel according to an embodiment of the disclosure.

FIG. 5 is an equivalent circuit diagram of a pixel according to an embodiment of the disclosure.

FIGS. 6A and 6B are plan views illustrating a portion of the display panel according to an embodiment of the disclosure.

FIG. 7A is a cross-sectional view illustrating a first area of the display panel according to an embodiment of the disclosure.

FIG. 7B is a cross-sectional view illustrating a second area of the display panel according to an embodiment of the disclosure.

FIG. 8A is a plan view illustrating a portion of a first lower light shielding layer according to an embodiment of the disclosure.

FIG. 8B is a plan view illustrating a portion of a second lower light shielding layer according to an embodiment of the disclosure.

FIGS. 9A to 9C are views illustrating a light shielding layer of the first area and a light source image captured through the first area.

FIGS. 10A and 10B are views illustrating the light shielding layer of the first area and the light source image captured through the first area.

FIGS. 11A and 11B are views illustrating the light shielding layer of the first area and the light source image captured through the first area.

FIGS. 12A and 12B are views illustrating the light shielding layer of the first area and the light source image captured through the first area.

FIGS. 13A and 13B are views illustrating the light shielding layer of the first area and the light source image captured through the first area.

FIGS. 14A and 14B are views illustrating the light shielding layer of the first area and the light source image captured through the first area.

FIGS. 15A and 15B are views illustrating the light shielding layer of the first area and the light source image captured through the first area.

FIGS. 16A and 16B are views illustrating the light shielding layer of the first area and the light source image captured through the first area.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. In the specification, the expression that a first component (or an area, a layer, a part, a portion, etc.) is “connected with” or “coupled to” a second component means that the first component is directly disposed on/connected with/coupled to the second component or means that a third component is interposed therebetween.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical terms and scientific terms) used in the specification have the same meaning as commonly understood by those skilled in the art to which the disclosure belongs. Further, terms defined in commonly used dictionaries should be construed as having the same meanings as those in the context of the related art, and may be explicitly defined therein unless the terms are interpreted in an ideal or excessive formal meaning.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings.

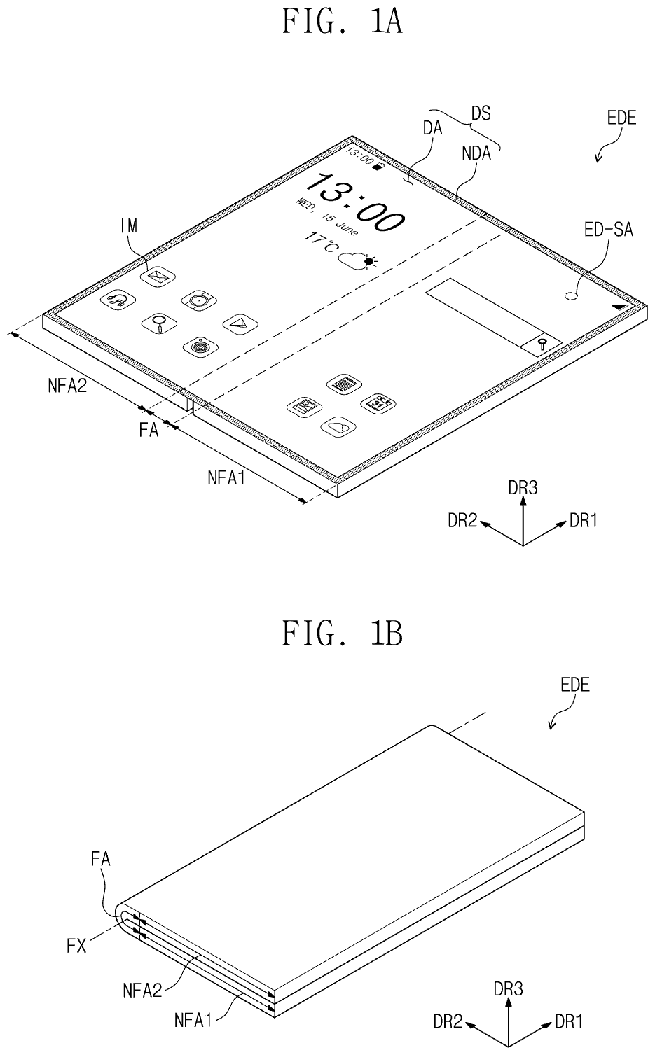

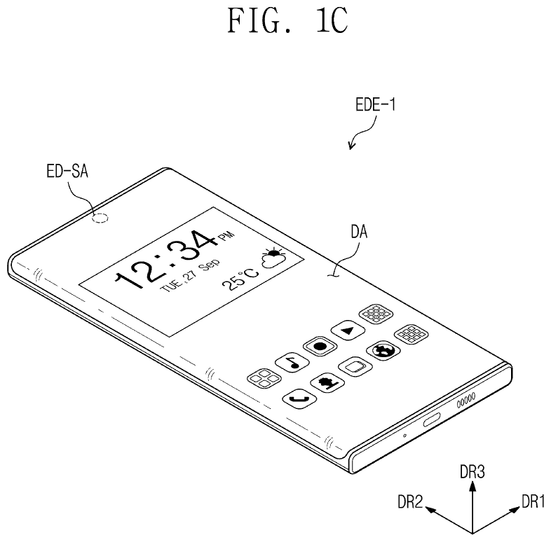

FIGS. 1A to 1C are perspective views of an electronic device according to an embodiment of the disclosure. FIG. 1A illustrates an electronic device EDE in an unfolded state, and FIG. 1B illustrates the electronic device EDE in a folded state. FIG. 1C illustrates an embodiment where the electronic device is a bar-type electronic device EDE-1.

Referring to FIGS. 1A and 1B, the electronic device EDE according to an embodiment of the disclosure may include a display surface DS on a plane defined by a first direction DR1 and a second direction DR2 intersecting the first direction DR1. The electronic device EDE may provide an image IM to a user through the display surface DS.

The display surface DS may include a display area DA and a non-display area NDA around the display area DA. The display area DA may display the image IM, and the non-display area NDA may not display the image IM. The non-display area NDA may surround the display area DA in a plan view or when viewed in a thickness direction perpendicular to the display surface DS. However, the disclosure is not limited thereto, and the shape of the display area DA and the shape of the non-display area NDA may be modified.

Hereinafter, a direction substantially perpendicular to a plane defined by the first direction DR1 and the second direction DR2 is defined as a third direction DR3. Here, the third direction DR3 may be a thickness direction of the electronic device EDE. Further, in the specification, the meaning of “on a plane” or “in a plan view” may be defined as a state of being viewed in the third direction DR3.

A sensor area ED-SA may be defined within the display area DA of the electronic device EDE. FIG. 1A illustrates an embodiment including a single sensor area ED-SA as an example, but the number of sensor areas ED-SA is not limited thereto. The sensor area ED-SA may be a portion of the display area DA. Thus, the electronic device EDE may display an image through the sensor area ED-SA.

In an embodiment, an electronic module may be disposed in a portion overlapping the sensor area ED-SA. The electronic module may receive an external input transmitted through the sensor area ED-SA or provide an output through the sensor area ED-SA. In an embodiment, for example, the electronic module may be a camera module, a sensor, such as a proximity sensor, which measures a distance, a sensor that recognizes a portion of a body (e.g., a fingerprint, an iris, or a face) of the user, or a small lamp that outputs a light, but the disclosure is not particularly limited thereto. Hereinafter, for convenience of description, embodiments in which the electronic module overlapping the sensor area ED-SA is a camera module will be mainly described as an example.

The electronic device EDE may include a folding area FA and a plurality of non-folding areas NFA1 and NFA2. The non-folding areas NFA1 and NFA2 may include the first non-folding area NFA1 and the second non-folding area NFA2. The folding area FA may be disposed between the first non-folding area NFA1 and the second non-folding area NFA2. The folding area FA may refer to a foldable area, and the first and second non-folding areas NFA1 and NFA2 may refer to first and second non-foldable areas.

In an embodiment, as illustrated in FIG. 1B, the folding area FA may be folded about a folding axis FX parallel to the first direction DR1. In a state in which the electronic device EDE is folded, the folding area FA has a predetermined curvature and a predetermined radius of curvature. In such a folded state, the first non-folding area NFA1 and the second non-folding area NFA2 may face each other, and the electronic device EDE may be inner-folded such that the display surface DS is not exposed to the outside.

In an embodiment of the disclosure, the electronic device EDE may be outer-folded such that the display surface DS is exposed to the outside. In an embodiment of the disclosure, the electronic device EDE may be inner-folded or outer-folded from an unfolding operation, but the disclosure is not limited thereto. In an embodiment of the disclosure, the electronic device EDE may selectively perform one of the unfolding operation, the inner-folding operation, and the outer-folding operation. In an embodiment of the disclosure, a plurality of folding axes are defined in the electronic device EDE, and the electronic device may be inner-folded or outer-folded from the unfolding operation on each of the plurality of folding axes.

In an embodiment, as illustrated in FIG. 1C, an electronic device EDE-1 may be a bar-type device that does not include the folding area FA. In an embodiment, the electronic device EDE-1 may provide the planar display area DA having long sides extending in the second direction DR2 and short sides extending in the first direction DR1, and the sensor area ED-SA may be provided to the same display surface as that of the display area DA.

It will be understood that the electronic device EDE or EDE-1 according to an embodiment of the disclosure described herein may be applied to various electronic devices such as a rollable electronic device, a slidable electronic device, and a stretchable electronic device, but the disclosure is not limited to an embodiment.

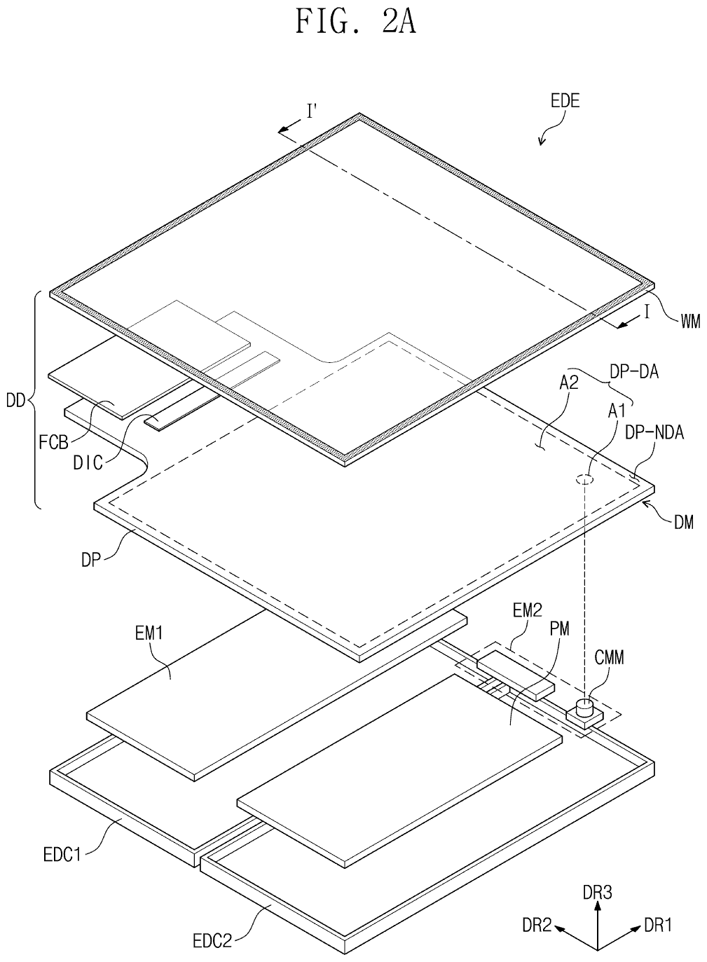

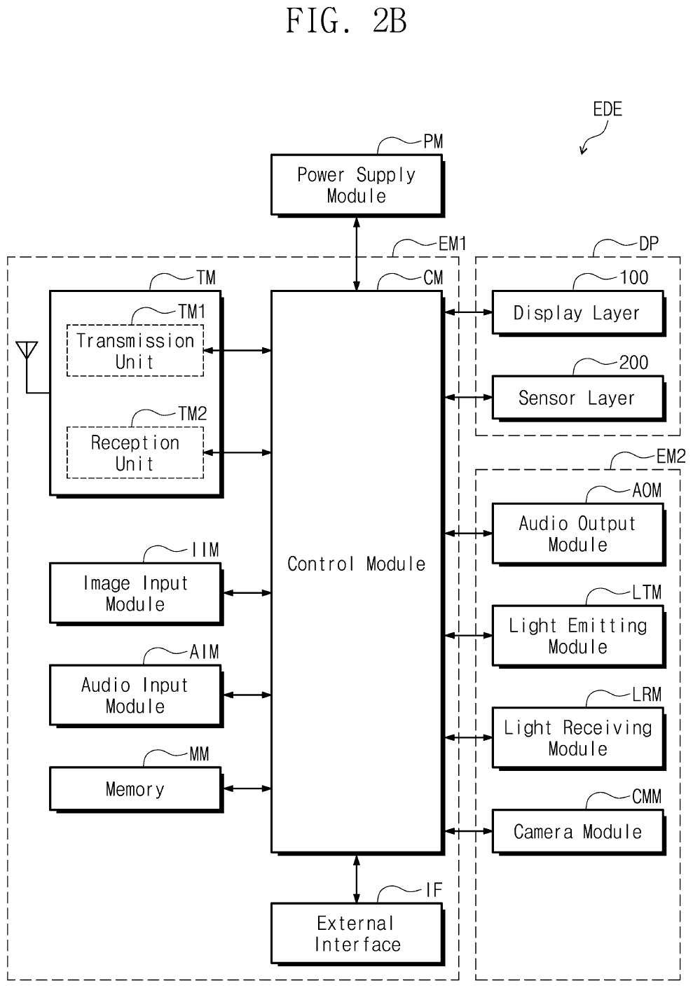

FIG. 2A is an exploded perspective view of the electronic device according to an embodiment of the disclosure. FIG. 2B is a block diagram of the electronic device according to an embodiment of the disclosure.

Referring to FIGS. 2A and 2B, an embodiment of the electronic device EDE may include a display device DD, a first electronic module EM1, a second electronic module EM2, a power supply module PM, and housings EDC1 and EDC2. The electronic device EDE may further include a mechanism structure for controlling a folding operation of the display device DD.

The display device DD includes a window module WM and a display module DM. The window module WM provides a front surface of the electronic device EDE. The display module DM may include at least a display panel DP. The display module DM generates an image and senses an external input.

FIG. 2A illustrates an embodiment where the display module DM is substantially the same as the display panel DP, and the display module DM may be a laminated structure in which a plurality of components including the display panel DP are laminated. The laminated structure of the display module DM will be described below.

The display panel DP includes a display area DP-DA and a non-display area DP-NDA respectively corresponding to the display area DA (see FIG. 1A) and the non-display area NDA (see FIG. 1A) of the electronic device EDE. In the specification, an expression “an area/part and an area/part correspond to each other” means that the area/part and the area/part overlap each other in the third direction DR3 and is not limited to the same area.

The display area DP-DA may include a first area A1 and a second area A2. The second area A2 may be spaced apart from or adjacent to the first area A1.

The first area A1 may overlap or correspond to the sensor area ED-SA (see FIG. 1) of the electronic device EDE. In an embodiment, the first area A1 has a circular shape in a plan view, but may have one of other various shapes such as a polygon, an ellipse, a figure having at least one curved side, or an atypical shape, and the disclosure is not limited to an embodiment.

The first area A1 may be referred to as a component area, and the second area A2 may be referred to as a main display area or a general display area. The first area A1 may have higher transmittance than that of the second area A2. Alternatively, a resolution of the first area A1 may be lower than a resolution of the second area A2, but the disclosure is not limited thereto. In an embodiment, for example, the first area A1 has the higher transmittance than that of the second area A2, but the resolution of the first area A1 may be substantially the same as the resolution of the second area A2. The first area A1 may overlap a camera module CMM in a plan view or in the third direction DR3, which will be described below.

The display panel DP may include a display layer 100 and a sensor layer 200.

The display layer 100 may be a component which substantially generates an image. The display layer 100 may be a light emitting display layer. In an embodiment, for example, the display layer 100 may be an organic light emitting display layer, an inorganic light emitting display layer, an organic-inorganic light emitting display layer, a quantum dot display layer, a micro-light emitting diode (LED) display layer, or a nano-LED display layer.

The sensor layer 200 may sense an external input applied from an external unit. The external input may be input of the user. The input of the user may include various types of external inputs such as a portion of the body of the user, light, heat, a pen, and pressure.

The display module DM may include a driving chip DIC disposed on the non-display area DP-NDA. The display module DM may further include a flexible circuit film FCB coupled to the non-display area DP-NDA.

The driving chip DIC may include driving elements, for example, a data driving circuit, for driving pixels of the display panel DP. Although an embodiment having a structure in which the driving chip DIC is mounted on the display panel DP is illustrated in FIG. 2A, the disclosure is not limited thereto. In another embodiment, for example, the driving chip DIC may be mounted on the flexible circuit film FCB.

The power supply module PM supplies power required for an overall operation of the electronic device EDE. The power supply module PM may include a general battery module.

The first electronic module EM1 and the second electronic module EM2 may include various functional modules for operating the electronic device EDE. Each of the first electronic module EM1 and the second electronic module EM2 is directly mounted on a motherboard electrically connected to the display panel DP or may be mounted on a separate board and electrically connected to the motherboard through a connector or the like.

In an embodiment, as shown in FIG. 2B, the first electronic module EM1 may include a control module CM, a wireless communication module TM, an image input module IIM, an audio input module AIM, a memory MM, and an external interface IF.

The control module CM controls an overall operation of the electronic device EDE. The control module CM may be a micro-processor. In an embodiment, for example, the control module CM activates or deactivates the display panel DP. The control module CM may control other modules such as the image input module IIM and the audio input module AIM based on a touch signal received from the display panel DP.

The wireless communication module TM may communicate with an external electronic device through a first network (e.g., a short-range communication network such as Bluetooth, Wi-Fi direct, or infrared data association (IrDA)) or a second network (e.g., a telecommunication network such as a cellular network, the Internet, or a computer network (e.g., a local area network (LAN) or a wide area network (WAN)). Communication modules included in the wireless communication module TM may be integrated into one component (e.g., a single chip) or may be implemented as a plurality of components (e.g., a plurality of chips) separated from each other. The wireless communication module TM may transmit/receive an audio signal using a general communication line. The wireless communication module TM may include a transmission unit TM1 for modulating and transmitting a signal to be transmitted and a reception unit TM2 for demodulating a received signal.

The image input module IIM processes and converts an image signal into image data that may be displayed on the display panel DP. The audio input module AIM receives an external audio signal through a microphone in a recording mode, a voice recognizing mode, and the like and converts the received external audio signal into electrical voice data.

The external interface IF may include a connector that may physically connect the electronic device EDE and the external electronic device. In an embodiment, for example, the external interface IF serves as an interface between the control module CM and an external device such as an external charger, a wired/wireless data port, and a card (e.g., a memory card and a subscriber identification module (SIM)/user identification module (UIM) card).

The second electronic module EM2 may include an audio output module AOM, a light emitting module LTM, a light receiving module LRM, the camera module CMM, or the like. The audio output module AOM converts audio data received from the wireless communication module TM or audio data stored in the memory MM and output the converted data to the outside.

The light emitting module LTM generates and outputs a light. The light emitting module LTM may output an infrared light. The light emitting module LTM may include a light emitting diode (LED) element. The light receiving module LRM may sense an infrared light. The light receiving module LRM may be activated when the infrared light having a predetermined level or higher is sensed. The light receiving module LRM may include a complementary metal-oxide semiconductor (CMOS) sensor. The infrared light generated by the light emitting module LTM is output and then reflected by an external subject (e.g., a finger or a face of the user), and the reflected infrared light may be input to the light receiving module LRM.

The camera module CMM may capture a still image and a video. The camera module CMM may be provided in plural as a plurality of camera modules CMM. In an embodiment, some camera modules CMM among the plurality of camera modules CMM may overlap the first area A1. The external input (e.g., a light) may be provided to the camera module CMM through the first area A1. In an embodiment, for example, the camera module CMM may capture an external image by receiving a natural light through the first area A1.

The housings EDC1 and EDC2 accommodate the display module DM, the first and second electronic modules EM1 and EM2, and the power supply module PM. The housings EDC1 and EDC2 protect components accommodated in the housings EDC1 and EDC2, such as the display module DM, the first and second electronic modules EM1 and EM2, and the power supply module PM. FIG. 2A illustrates an embodiment including two housings EDC1 and EDC2 separated from each other as an example, but the disclosure is not limited thereto. Although not illustrated, the electronic device EDE may further include a hinge structure for connecting the two housings EDC1 and EDC2. The housings EDC1 and EDC2 may be coupled to the window module WM.

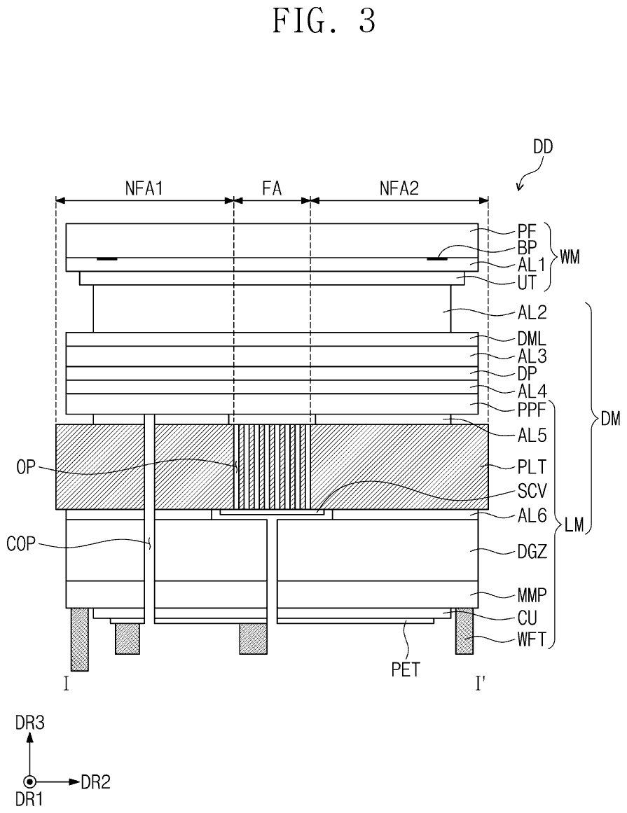

FIG. 3 is a cross-sectional view of a display device according to an embodiment of the disclosure. FIG. 3 may correspond to a cross-sectional view taken along line I-I′ in FIG. 2A. Hereinafter, a display device DD according to an embodiment of the disclosure will be described in detail with reference to FIG. 3.

In an embodiment, the display device DD may include the window module WM and the display module DM. The window module WM may include a window UT, a protective film PF disposed on the window UT, and a bezel pattern BP.

The window UT may be a chemically reinforced glass. In such an embodiment where the chemically reinforced glass is applied to the display device DD as the window UT, occurrence of wrinkles may be minimized even when folding and unfolding are repeated. However, this is illustratively described, the window UT may be a flexible film containing a thin glass, a coated glass, a resin or the like, and the disclosure is not limited to an embodiment.

The protective film PF may include polyimide, polycarbonate, polyamide, triacetylcellulose, polymethylmethacrylate, or polyethylene terephthalate. Although not separately illustrated, at least one selected from a hard coating layer, a fingerprint preventing layer, and a reflection preventing layer may be further disposed on an upper surface of the protective film PF.

The bezel pattern BP overlaps the non-display area NDA (see FIG. 1A). The bezel pattern BP may be disposed on one surface of the window UT or one surface of the protective film PF. FIG. 3 illustrates an embodiment where the bezel pattern BP is disposed on a lower surface of the protective film PF. However, the disclosure is not limited thereto, and the bezel pattern BP may be disposed on the upper surface of the protective film PF, an upper surface of the window UT, or a lower surface of the window UT. The bezel pattern BP may be a colored light shielding film, and may be formed by, for example, a coating method. The bezel pattern BP may include a base material and a dye or pigment mixed with the base material. The bezel pattern BP may have a closed line shape on a plane.

A first adhesive layer AL1 may be disposed between the protective film PF and the window UT. The first adhesive layer AL1 may be a pressure sensitive adhesive (PSA) film or an optically clear adhesive (OCA) member. Adhesive layers, which will be described below, are also the same as the first adhesive layer AL1 and may include common adhesives.

The first adhesive layer AL1 may have a thickness enough to cover the bezel pattern BP. The first adhesive layer AL1 may have a thickness at which bubbles are not generated around the bezel pattern BP.

The first adhesive layer AL1 may be separated from the window UT. Since the protective film PF has a lower strength than that of the window UT, scratches may occur relatively easily. After the first adhesive layer AL1 and the damaged protective film PF are separated from the window UT, a new protective film PF may be attached to the window UT. Accordingly, the protective film PF or the window UT may be easily replaced. However, this is illustratively illustrated, and the protective film PF may be directly formed on the window UT by a manner such as coating without the first adhesive layer AL1 or may be omitted, but the disclosure is not limited to an embodiment.

The display module DM may include an impact absorbing layer DML, the display panel DP, and a lower member LM.

The impact absorbing layer DML may be disposed on the display panel DP. The impact absorbing layer DML may be a functional layer for protecting the display panel DP from an external impact. The impact absorbing layer DML may be coupled to the window UT through a second adhesive layer AL2 and coupled to the display panel DP through a third adhesive layer AL3.

The lower member LM may be disposed under the display panel DP. The lower member LM may include a panel protecting layer PPF, a support layer PLT, a cover layer SCV, a digitizer DGZ, a shielding layer MMP, a heat dissipating layer CU, a protective layer PET, and a waterproof tape WFT. In an embodiment of the disclosure, the lower member LM may not include some of the above-described components or may further include other components. Further, a laminate sequence illustrated in FIG. 3 is merely shown as an example, and the laminate sequence of the respective components may be also variously modified.

The panel protecting layer PPF may be disposed under the display panel DP. The panel protecting layer PPF may be attached to a rear surface of the display panel DP through a fourth adhesive layer AL4. The panel protecting layer PPF may protect a lower portion of the display panel DP. The panel protecting layer PPF may include a flexible plastic material. The panel protecting layer PPF may prevent scratches from occurring on the rear surface of the display panel DP during a process of manufacturing the display panel DP. The panel protecting layer PPF may be a colored polyimide film. In an embodiment, for example, the panel protecting layer PPF may be an opaque yellow film, but the disclosure is not limited thereto.

The support layer PLT is disposed under the panel protecting layer PPF. The support layer PLT supports components arranged on an upper side of the support layer PLT and maintains an unfolded state and a folded state of the display device DD. In an embodiment of the disclosure, the support layer PLT may include at least a first support part corresponding to the first non-folding area NFA1, a second support part corresponding to the second non-folding area NFA2, and a folding part corresponding to the folding area FA. The first support part and the second support part may be spaced apart from each other in the second direction DR2. The folding part may be disposed between the first support part and the second support part, and a plurality of openings OP may be defined in the folding part. Flexibility of a portion of the support layer PLT may be improved by the openings OP. Flexibility of a portion of the support layer PLT, which overlaps the folding area FA, may be improved by the openings OP.

In an embodiment, the support layer PLT may include a carbon fiber reinforced plastic (CFRP), but the disclosure is not particularly limited thereto. Alternatively, the first support part and the second support part may include a non-metallic material, a plastic, a glass fiber reinforced plastic, or a glass. The plastic may include polyimide, polyethylene, or polyethylene terephthalate, but the disclosure is not particularly limited thereto. The first support part and the second support part may include a same material as each other. The folding part may include the same material as that of the first support part and the second support part or may include a different material therefrom. In an embodiment, for example, the folding part may include a material having an elastic modulus of 60 gigapascals (GPa) or greater and may include a metallic material such as stainless steel. In an embodiment, for example, the folding part may include SUS 304, but the disclosure is not limited thereto, and the folding part may include various metallic materials.

The support layer PLT may be attached to the panel protecting layer PPF through a fifth adhesive layer AL5. The fifth adhesive layer AL5 may be provided as a plurality of fifth adhesive layers AL5, and the fifth adhesive layers AL5 may be spaced apart from each other with the folding area FA interposed therebetween. In an embodiment, the fifth adhesive layer AL5 may not overlap the plurality of openings OP. Alternatively, the fifth adhesive layer AL5 may be spaced apart from the plurality of openings OP on a plane. The fifth adhesive layer AL5 may not be disposed in an area corresponding to the folding area FA, thereby improving the flexibility of the support layer PLT.

In an embodiment, the panel protecting layer PPF may be spaced apart from the support layer PLT in an area that overlaps the folding area FA. That is, an empty space may be defined between the support layer PLT and the panel protecting layer PPF in a portion that overlaps the folding area FA. In such an embodiment where the empty space is defined between the panel protecting layer PPF and the support layer PLT, a shape of the plurality of openings OP defined in the support layer PLT may not be visually recognized from the outside of the electronic device EDE (see FIG. 1A).

A thickness of the fifth adhesive layer AL5 may be less than a thickness of the fourth adhesive layer AL4. As the thickness of the fifth adhesive layer AL5 becomes less, a step caused by the fifth adhesive layer AL5 may be reduced. As the step becomes less, deformation of shapes of the laminated structures due to the folding and the unfolding of the electronic device EDE (see FIG. 1A) may be reduced. However, the plurality of openings OP may be visually recognized or the fifth adhesive layer AL5 may be detached due to the repeated folding operation. As the thickness of the fifth adhesive layer AL5 becomes greater, the plurality of openings OP may not be visually recognized, and reliability of an adhesive force of the fifth adhesive layer AL5 may be increased despite the repeated folding operation, but the step may be increased. Thus, the thickness of the fifth adhesive layer AL5 may be selected within an appropriate range in consideration of folding reliability, adhesive reliability, and visibility of the plurality of openings OP.

The cover layer SCV may be disposed under the support layer PLT. The cover layer SCV may be coupled to the support layer PLT by an adhesive member. The cover layer SCV may cover the plurality of openings OP defined in the support layer PLT. Thus, the cover layer SCV may effectively prevent foreign substances from flowing into the plurality of openings OP. The cover layer SCV may have a lower elastic modulus than that of the support layer PLT. In an embodiment, for example, the cover layer SCV may include thermoplastic polyurethane, rubber, or silicone, but the disclosure is not limited thereto.

The digitizer DGZ may be disposed under the support layer PLT. The digitizer DGZ may be provided in plural as a plurality of digitizers DGZ. In an embodiment, for example, the plurality of digitizers DGZ may be spaced apart from each other in the second direction DR2. Portions of the plurality of digitizers DGZ may overlap the non-folding area NFA1 or NFA2, and the remaining portions thereof may overlap the folding area FA. On a plane, the portions of the plurality of digitizers DGZ may overlap portions of the plurality of openings OP.

Each of the plurality of digitizers DGZ may include a plurality of loop coils that generate a magnetic field having a preset resonant frequency with an input device (hereinafter, referred to as a pen). The plurality of digitizers DGZ may also be referred to as an EMR sensing panel. In an embodiment of the disclosure, the plurality of digitizers DGZ may be omitted.

The magnetic field formed by the plurality of digitizers DGZ is applied to an LC resonance circuit including an inductor (coil) and a capacitor of the pen. The coil generates a current by the received magnetic field and transfers the generated current to the capacitor. Accordingly, the capacitor charges the current input from the coil and discharges the charged current to the coil. As a result, the magnetic field having the resonant frequency is emitted to the coil. The magnetic field emitted by the pen may be absorbed by the loop coils of the plurality of digitizers DGZ again, and accordingly, which position of the plurality of digitizers DGZ the pen is adjacent to may be determined.

The shielding layers MMP may be arranged under the plurality of digitizers DGZ, respectively. Each of the shielding layers MMP may include magnetic metal powder. The shielding layers MMP may be referred to as a magnetic metal powder layer, a magnetic layer, a magnetic circuit layer, or a magnetic path layer. The shielding layers MMP may shield the magnetic field.

The heat dissipating layers CU may be arranged under the shielding layers MMP, respectively. The heat dissipating layers CU may be sheets having high thermal conductivity. In an embodiment, for example, each of the heat dissipating layers CU may include graphite, copper, or a copper alloy, but the disclosure is not particularly limited thereto.

The protective layers PET may be arranged under the heat dissipating layers CU, respectively. The protective layers PET may be insulating layers. In an embodiment, for example, the protective layers PET may be layers provided to effectively prevent inflow of static electricity. Thus, electrical interference between the flexible circuit film FCB (see FIG. 2A) and members arranged on the protective layers PET may be prevented by the protective layers PET.

The waterproof tapes WFT may be attached to the shielding layers MMP and the protective layers PET. The waterproof tape WFT may be attached to a set bracket (not illustrated). Among the waterproof tapes WFT, a thickness of the waterproof tape attached to the shielding layers MMP and a thickness of the waterproof tape attached to the protective layers PET may be different from each other.

Through-holes COP may be defined in at least some of components constituting the lower member LM. The through-hole COP may overlap or correspond to the sensor area ED-SA (see FIG. 1A) of the electronic device EDE in the third direction Dr3. At least a portion of the camera module CMM (see FIG. 2A) may be inserted into the through-hole COP.

FIG. 3 illustrates an embodiment where the through-hole COP is provided from a rear surface of one protective layer among the protective layers PET to the fifth adhesive layer AL5 as an example, but the disclosure is not limited thereto. In another embodiment, for example, the through-hole COP may be provided from the rear surface of the one protective layer to an upper surface of the panel protecting layer PPF or from the rear surface of the one protective layer to an upper surface of the fourth adhesive layer AL4.

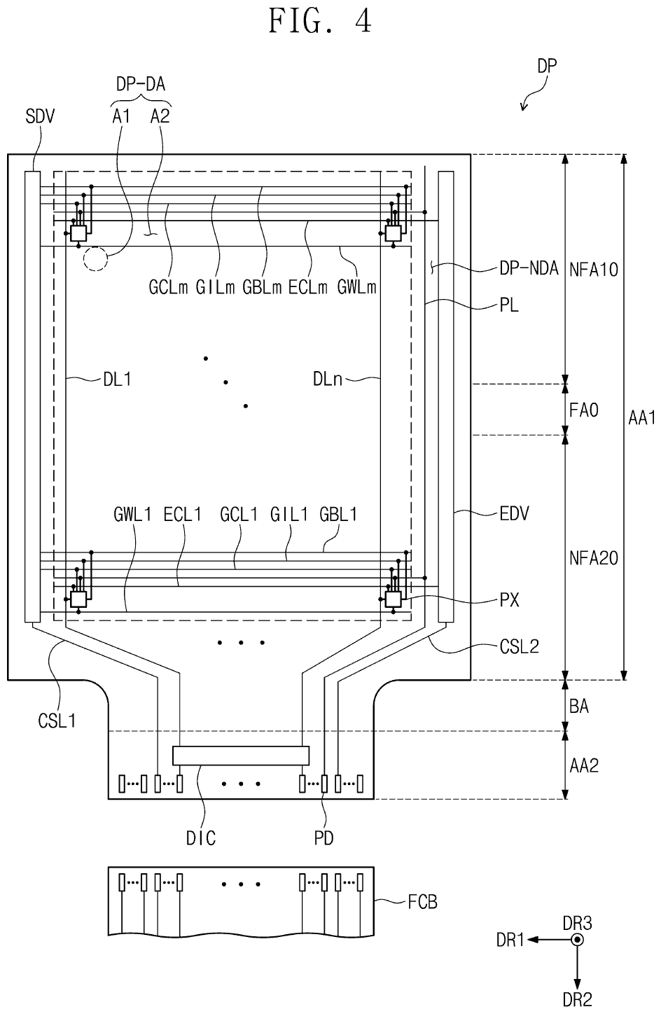

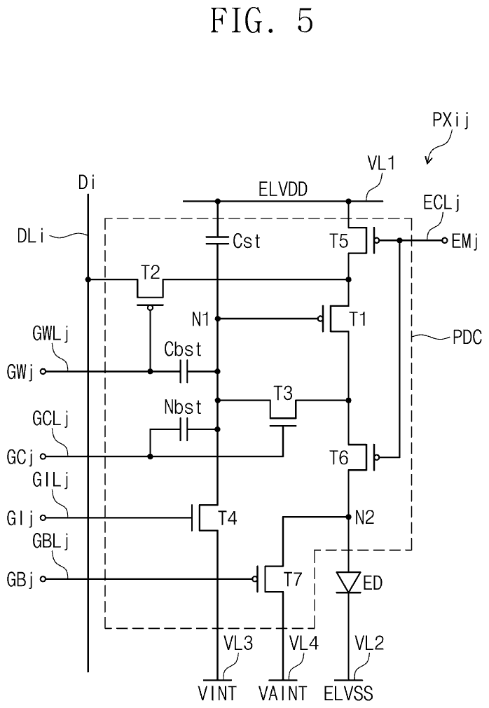

FIG. 4 is a plan view of a display panel according to an embodiment of the disclosure. FIG. 5 is an equivalent circuit diagram of a pixel according to an embodiment of the disclosure. Hereinafter, the display panel DP according to an embodiment of the disclosure will be described in detail with reference to FIGS. 4 and 5.

Referring to FIG. 4, in an embodiment, the display area DP-DA and the non-display area DP-NDA around the display area DP-DA may be defined in the display panel DP. The display area DP-DA and the non-display area DP-NDA may be distinguished from each other depending on whether a pixel PX is disposed. The pixel PX is disposed in the display area DP-DA. A scan driving unit SDV, a data driving unit, and a light emitting driving unit EDV may be arranged in the non-display area DP-NDA. The data driving unit may be a portion of a circuit included in the driving chip DIC.

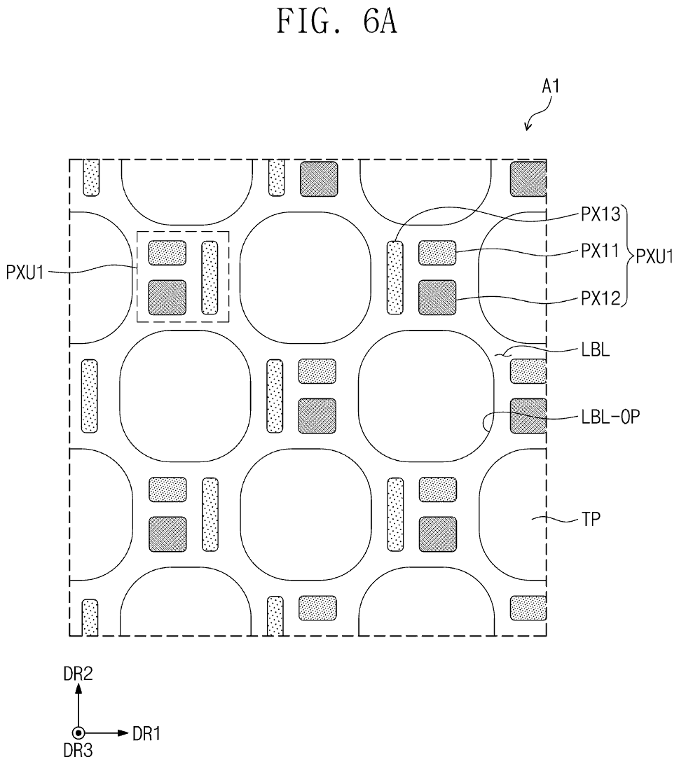

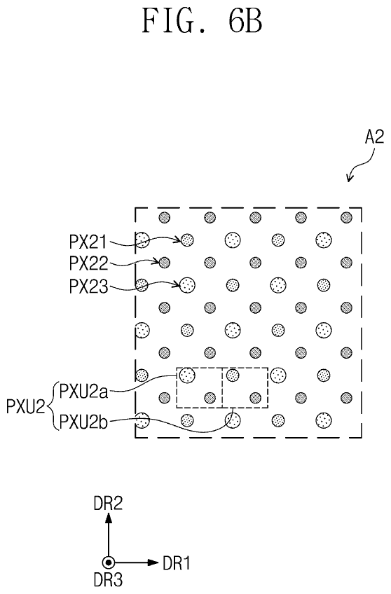

The display area DP-DA may include the first area A1 and the second area A2. The first area A1 and the second area A2 may be distinguished from each other based on an arrangement interval of the pixels PX, a size of the pixels PX, a shape of the pixels PX, or the presence or absence of a transmissive area TP (see FIG. 6A).

The display panel DP may include a first panel area AA1, a bending area BA, and a second panel area AA2 defined in the second direction DR2. The second panel area AA2 and the bending area BA may be partial areas of the non-display area DP-NDA. The bending area BA is disposed between the first panel area AA1 and the second panel area AA2.

The first panel area AA1 is an area corresponding to the display surface DS of FIG. 1A. The first panel area AA1 may include a first non-folding area NFA10, a second non-folding area NFA20, and a folding area FAO. The first non-folding area NFA10, the second non-folding area NFA20, and the folding area FAO respectively correspond to the first non-folding area NFA1, the second non-folding area NFA2, and the folding area FA in FIGS. 1A and 1B.

A width of the bending area BA and a width (or a length) of the second panel area AA2, which are parallel to the first direction DR1, may be less than a width (or a length) of the first panel area AA1 parallel to the first direction DR1. An area having a shorter length in a bending axis direction may be more easily bent.

The display panel DP may include the pixels PX, initialization scan lines GIL1 to GILm, compensation scan lines GCL1 to GCLm, write scan lines GWL1 to GWLm, black scan lines GBL1 to GBLm, light emitting control lines ECL1 to ECLm, data lines DL1 to DLn, first and second control lines CSL1 and CSL2, a driving voltage line PL, and a plurality of pads PD. Here, ‘m’ and ‘n’ are natural numbers greater than or equal to two.

The pixels PX may be connected to the initialization scan lines GIL1 to GILm, the compensation scan lines GCL1 to GCLm, the write scan lines GWL1 to GWLm, the black scan lines GBL1 to GBLm, the light emitting control lines ECL1 to ECLm, and the data lines DL1 to DLn.

The initialization scan lines GIL1 to GILm, the compensation scan lines GCL1 to GCLm, the write scan lines GWL1 to GWLm, and the black scan lines GBL1 to GBLm may extend in the first direction DR1 and may be electrically connected to the scan driving unit SDV. The data lines DL1 to DLn may extend in the second direction DR2 and may be electrically connected to the driving chip DIC via the bending area BA. The light emitting control lines ECL1 to ECLm may extend in a direction parallel to the first direction DR1 and may be electrically connected to the light emitting driving unit EDV.

The driving voltage line PL may include a portion extending in the first direction DR1 and a portion extending in the second direction DR2. The portion extending in the first direction DR1 and the portion extending in the second direction DR2 may be arranged in different layers. A portion of the driving voltage line PL, which extends in the second direction DR2, may extend to the second panel area AA2 via the bending area BA. The driving voltage line PL may provide a driving voltage to the pixels PX.

The first control line CSL1 may be connected to the scan driving unit SDV and may extend toward a lower end of the second panel area AA2 via the bending area BA. The second control line CSL2 may be connected to the light emitting driving unit EDV and may extend toward the lower end of the second panel area AA2 via the bending area BA.

In a plan view or on a plane, the pads PD may be arranged adjacent to the lower end of the second panel area AA2. The driving chip DIC, the driving voltage line PL, the first control line CSL1, and the second control line CSL2 may be electrically connected to the pads PD. The flexible circuit film FCB may be electrically connected to the pads PD through an anisotropic conductive adhesive layer.

FIG. 5 illustrates an equivalent circuit diagram of an embodiment of one pixel PXij among the plurality of pixels PX (see FIG. 4) as an example. Since the plurality of pixels PX have the same circuit structure, any repetitive detailed description of circuit structure of the other pixels PX will be omitted.

Referring to FIGS. 4 and 5, the pixel PXij is connected to an i^{th} data line DLi among the data lines DL1 to DLn, a j^{th} initialization scan line GILj among the initialization scan lines GIL1 to GILm, a j^{th} compensation scan line GCLj among the compensation scan lines GCL1 to GCLm, a j^{th} write scan line GWLj among the write scan lines GWL1 to GWLm, a j^{th} black scan line GBLj among the black scan lines GBL1 to GBLm, a j^{th} light emitting control line ECLj among the light emitting control lines ECL1 to ECLm, first and second driving voltage lines VL1 and VL2, and first and second initialization voltage lines VL3 and VL4. Herein, ‘i’ is an integer greater than or equal to 1 and less than or equal to ‘n’, and ‘j’ is an integer greater than or equal to 1 and less than or equal to ‘m’.

The pixel PXij includes a light emitting element ED and a pixel circuit PDC. The light emitting element ED may be a light emitting diode. In an embodiment of the disclosure, for example, the light emitting element ED may be an organic light emitting diode including an organic light emitting layer, but the disclosure is not particularly limited thereto. The pixel circuit PDC may control the amount of a current flowing in the light emitting element ED in response to a data signal Di. The light emitting element ED may emit a light having a predetermined luminance to correspond to the amount of current provided from the pixel circuit PDC. In the disclosure, the amount of current of the pixel PXij may mean the amount of current provided to the light emitting element ED.

The pixel circuit PDC may include first to seventh transistors T1, T2, T3, T4, T5, T6, and T7, and first to third capacitors Cst, Cbst, and Nbest. According to embodiments of the disclosure, a configuration of the pixel circuit PDC is not limited to an embodiment illustrated in FIG. 5. The pixel circuit PDC illustrated in FIG. 5 is merely an example, and a configuration of the pixel circuit PDC may be variously modified and implemented.

At least one of the first to seventh transistors T1, T2, T3, T4, T5, T6, and T7 may be a transistor having a low-temperature polycrystalline silicon (LTPS) semiconductor layer. At least one of the first to seventh transistors T1, T2, T3, T4, T5, T6, and T7 may be a transistor having an oxide semiconductor layer. In an embodiment, for example, the third and fourth transistors T3 and T4 may be oxide semiconductor transistors, and the first, second, fifth, sixth, and seventh transistors T1, T2, T5, T6, and T7 may be LTPS transistors.

In an embodiment, the first transistor T1 (or referred to as a driving transistor), which directly affects the brightness of the light emitting element ED, includes a highly reliable polycrystalline silicon semiconductor layer, and therefore, a high-resolution display device may be implemented. In such an embodiment, because the oxide semiconductor has high carrier mobility and a low leakage current, a voltage drop is not large even when a driving time is long. That is, because a change in a color of the image due to the voltage drop is not large even during low-frequency driving, the low-frequency driving may be performed. In this way, because the oxide semiconductor has a low leakage current, at least one among the third transistor T3 and the fourth transistor T4 connected to a gate electrode of the first transistor T1 may be adopted as the oxide transistor, and thus leakage current that may flow to the gate electrode may be effectively prevented, and at the same time, power consumption may be substantially reduced.

Some of the first to seventh transistors T1, T2, T3, T4, T5, T6, and T7 may be P-type transistors and the other thereof may be N-type transistors. In an embodiment, for example, the first, second, fifth, sixth, and seventh transistors T1, T2, T5, T6, and T7 may be P-type transistors, and the third and fourth transistors T3 and T4 may be N-type transistors.

A configuration of the pixel circuit PDC according to embodiments of the disclosure is not limited to an embodiment illustrated in FIG. 5. The pixel circuit PDC illustrated in FIG. 5 is merely an example and a configuration of the pixel circuit PDC may be variously modified and implemented. In an embodiment, for example, all the first to seventh transistors T1, T2, T3, T4, T5, T6, and T7 may be P-type transistors or N-type transistors. Alternatively, the first, second, fifth, and sixth transistors T1, T2, T5, and T6 may be P-type transistors, and the third, fourth, and seventh transistors T3, T4 and T7 may be N-type transistors.

The j^{th} initialization scan line GILj, the j^{th} compensation scan line GCLj, the j^{th} write scan line GWLj, the j^{th} black scan line GBLj, and the j^{th} light emitting control line ECLj may transmit, to the pixel PXij, a j^{th} initialization scan signal GIj, a j^{th} compensation scan signal GCj, a j^{th} write scan signal GWj, a j^{th} black scan signal GBj, and a j^{th} light emitting control signal EMj, respectively. The i^{th} data line DLi transmits an i^{th} data signal Di to the pixel PXij. The i^{th} data signal Di may have a voltage level corresponding to an image signal input to the display device DD (see FIG. 3).

The first and second driving voltage lines VL1 and VL2 may transmit, to the pixel PXij, a first driving voltage ELVDD and a second driving voltage ELVSS, respectively. Further, the first and second initialization voltage lines VL3 and VL4 may transmit, to the pixel PXij, a first initialization voltage VINT and a second initialization voltage VAINT, respectively.

The first transistor T1 is connected between the first driving voltage line VL1 that receives the first driving voltage ELVDD and the light emitting element ED. The first transistor T1 includes a first electrode connected to the first driving voltage line VL1 via the fifth transistor T5, a second electrode connected to a pixel electrode (or referred to as an anode) of the light emitting element ED via the sixth transistor T6, and a third electrode (e.g., a gate electrode) connected to one end (e.g., a first node N1) of the first capacitor Cst. The first transistor T1 may receive the i^{th} data signal Di transmitted by the i^{th} data line DLi based on a switching operation of the second transistor T2 and supply a driving current to the light emitting element ED.

The second transistor T2 is connected between the data line DLi and the first electrode of the first transistor T1. The second transistor T2 includes a first electrode connected to the data line DLi, a second electrode connected to the first electrode of the first transistor T1, and a third electrode (e.g., a gate electrode) connected to the j^{th} write scan line GWLj. The second transistor T2 may be turned on in response to the write scan signal GWj received through the j^{th} write scan line GWLj and may transmit the i^{th} data signal Di transmitted from the i^{th} data line DLi to the first electrode of the first transistor T1. One end of the second capacitor Cbst may be connected to the third electrode of the second transistor T2, and the other end of the second capacitor Cbst may be connected to the first node N1.

The third transistor T3 is connected between the second electrode of the first transistor T1 and the first node N1. The third transistor T3 includes a first electrode connected to the third electrode of the first transistor T1, a second electrode connected to the second electrode of the first transistor T1, and a third electrode (e.g., a gate electrode) connected to the j^{th} compensation scan line GCLj. The third transistor T3 may be turned on in response to the j^{th} compensation scan signal GCj received through the j^{th} compensation scan line GCLj, may connect the third electrode of the first transistor T1 and the second electrode of the first transistor T1 to each other, and thus may diode-connect the first transistor T1. One end of the third capacitor Nbst may be connected to the third electrode of the third transistor T3, and the other end of the third capacitor Nbst may be connected to the first node N1.

The fourth transistor T4 is connected between the first initialization voltage line VL3 to which the first initialization voltage VINT is applied and the first node N1. The fourth transistor T4 includes a first electrode connected to the first initialization voltage line VL3 to which the first initialization voltage VINT is transmitted, a second electrode connected to the first node N1, and a third electrode (e.g., a gate electrode) connected to the j^{th} initialization scan line GILj. The fourth transistor T4 is turned on in response to the j^{th} initialization scan signal GIj received through the j^{th} initialization scan line GILj. The turned-on fourth transistor T4 transmits the first initialization voltage VINT to the first node N1 and initializes a potential of the third electrode of the first transistor T1 (i.e., a potential of the first node N1).

The fifth transistor T5 includes a first electrode connected to the first driving voltage line VL1, a second electrode connected to the first electrode of the first transistor T1, and a third electrode (e.g., a gate electrode) connected to the j^{th} light emitting control line ECLj. The sixth transistor T6 includes a first electrode connected to the second electrode of the first transistor T1, a second electrode connected to the pixel electrode (e.g., a second node N2) of the light emitting element ED, and a third electrode (e.g., a gate electrode) connected to the j^{th} light emitting control line ECLj.

The fifth and sixth transistors T5 and T6 are simultaneously turned on in response to the j^{th} light emitting control signal EMj received through the j^{th} light emitting control line ECLj. The first driving voltage ELVDD applied through the turned-on fifth transistor T5 may be compensated for through the diode-connected first transistor T1 and then may be transmitted to the light emitting element ED through the sixth transistor T6.

The seventh transistor T7 includes a first electrode connected to the second initialization voltage line VL4 through which the second initialization voltage VAINT is transmitted, a second electrode electrically connected to the second electrode (e.g., the second node N2) of the sixth transistor T6, and a third electrode (e.g., a gate electrode) connected to the black scan line GBLj. The second initialization voltage VAINT may have a voltage level lower than or equal to the first initialization voltage VINT.

One end of the first capacitor Cst is connected to the third electrode of the first transistor T1, and the other end of the first capacitor Cst is connected to the first driving voltage line VL1. A cathode of the light emitting element ED may be connected to the second driving voltage line VL2 that transmits the second driving voltage ELVSS. The second driving voltage ELVSS may have a voltage level lower than that of the first driving voltage ELVDD.

FIGS. 6A and 6B are plan views illustrating a portion of the display panel according to an embodiment of the disclosure. FIG. 6A illustrates the first area A1 illustrated in FIG. 4, and FIG. 6B illustrates the second area A2 illustrated in FIG. 6B.

In an embodiment, as described above, the display panel DP includes the plurality of pixels PX. The pixels PX may include first pixels PX11, PX12, and PX13 arranged in the first area A1 and second pixels PX21, PX22, and PX23 arranged in the second area A2.

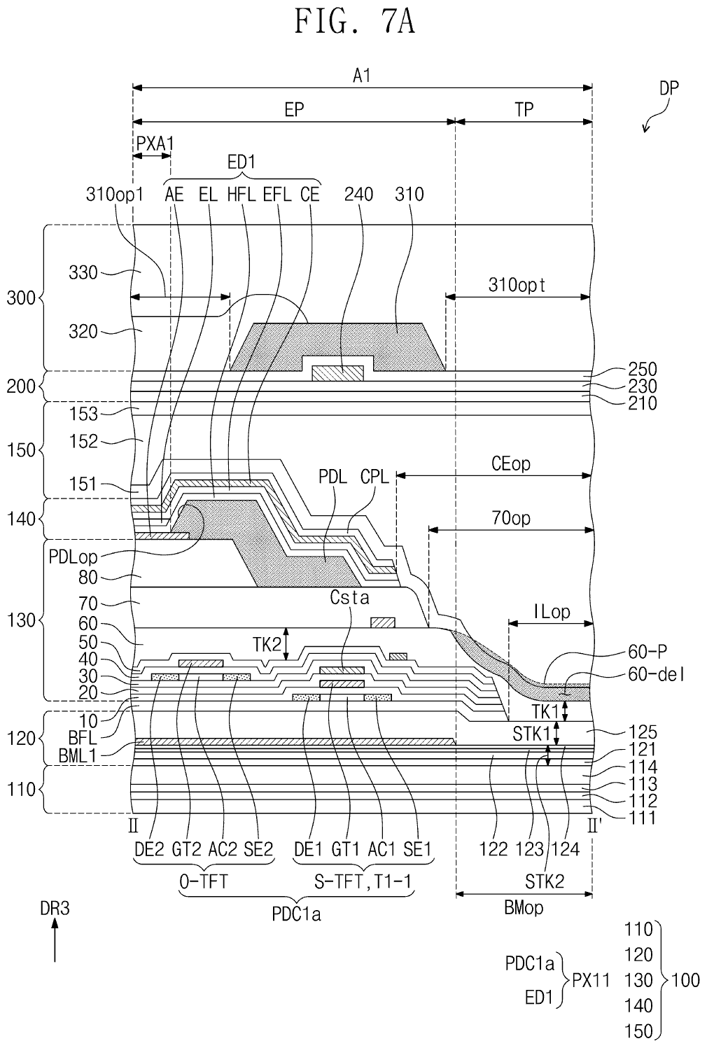

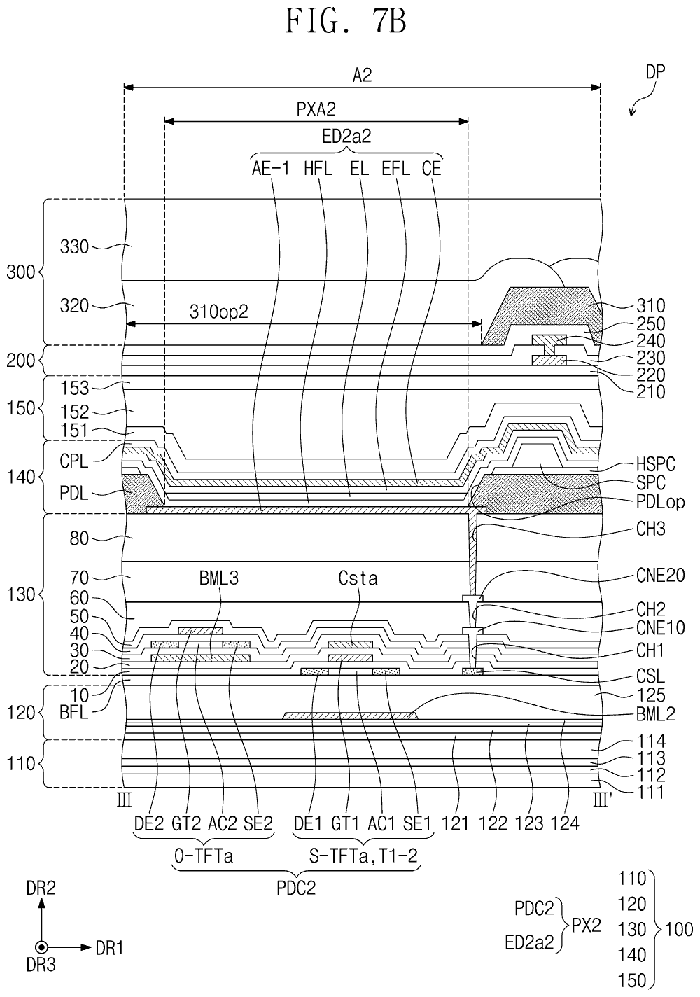

Referring to FIG. 6A, the first area A1 may include the transmissive area TP. The transmissive area TP may be an area having a relatively high transmittance compared to a peripheral area. In an embodiment, the transmissive area TP may be provided in plural as a plurality of transmissive areas TP. The plurality of transmissive areas TP may be spaced apart from each other within the first area A1. In an embodiment, each of the transmissive areas TP may be defined (provided or formed) by an opening LBL-OP defined or formed in a light shielding layer LBL. The light shielding layer LBL may be any one of a pixel defining layer PDL, lower light shielding layers BML1 and BML2 (see FIG. 7A), and a division layer 310 (see FIG. 7A), which will be described below.

A shape (or planar shape) of each of the transmissive areas TP (or the opening LBL-OP) may not be circular. In an embodiment, for example, the shape of each of the transmissive areas TP may be a closed line shape but may be a polygon, an irregular shape including curved lines and straight lines, or an irregular shape including curved lines having different curvatures. In an embodiment, for example, the shape of each of the transmissive areas TP may be squircle. Each of the transmissive areas TP may have various shapes as long as the shape is not circular, and the disclosure is not limited to an embodiment.

In an embodiment, the shapes of the transmissive areas TP may include at least N different shapes. That is, the shape of each of the transmissive areas TP may be one of the N shapes, and all the N shapes may be arranged in the first area A1. Here, N is a natural number equal to or greater than 2. Some of the N shapes may be plural, and the others thereof may be singular. That is, one of the transmissive areas TP within the first area A1 may have a same shape as another thereof, and another one thereof may have a unique shape different from the one thereof. Alternatively, each of the transmissive areas TP within the first area A1 may have a different shape or may have a same shape as at least the other one thereof. When the number of transmissive areas TP arranged in the first area A1 among the transmissive areas TP is M, N may be 4 or more and M or less. Here, M is a natural number greater than 4. Detailed features of the transmissive areas TP will be described below.

A first pixel unit PXU1 may be disposed in the first area A1. The first pixel unit PXU1 may be provided in plural as a plurality of first pixel units PXU1, which may be arranged between the transmissive areas TP. The first pixel unit PXU1 may include the first pixels PX11, PX12, and PX13. The first pixels PX11, PX12, and PX13 may include a first first color pixel (hereinafter, will be referred to as “(1-1)^{th} color pixel”) PX11, a second first color pixel (hereinafter, will be referred to as “(1-2)^{th} color pixel”) PX12, and a third first color pixel (hereinafter, will be referred to as “(1-3)^{th} color pixel”) PX13.

Referring to FIG. 6B, a second pixel unit PXU2 may be disposed in the second area A2. The second pixel unit PXU2 may include a first sub-pixel unit PXU2a and a second sub-pixel unit PXU2b. The first sub-pixel unit PXU2a may include a third second color pixel (hereinafter, will be referred to as “(2-3)^{th} color pixel”) PX23 and a second second color pixel (hereinafter, will be referred to as “(2-2)^{th} color pixel”) PX22. The second sub-pixel unit PXU2b may include a first second color pixel (hereinafter, will be referred to as “(2-1)^{th} color pixel”) PX21 and the (2-2)^{th} color pixel PX22.

The second pixels PX21, PX22, and PX23 may include the (2-1)^{th} color pixel PX21, the (2-2)^{th} color pixel PX22, and the (2-3)^{th} color pixel PX23. The (1-1)^{th} color pixel PX11 and the (2-1)^{th} color pixel PX21 may be red light emitting pixels, the (1-2)^{th} color pixel PX12 and the (2-2)^{th} color pixel PX22 may be green light emitting pixels, and the (1-3)^{th} color pixel PX13 and the (2-3)^{th} color pixel PX23 may be blue light emitting pixels.

A planar shape of each of the first pixels PX11, PX12, and PX13 illustrated in FIG. 6A and the second pixels PX21, PX22, and PX23 illustrated in FIG. 6B may correspond to a shape of a light emitting area defined in the light emitting element. The light emitting area may be an area defined by a pixel defining opening PDLop (see FIG. 7A) defined in the pixel defining layer PDL (see FIG. 7A). In an embodiment, an arrangement rule of the first pixels PX11, PX12, and PX13 arranged in the first area A1 or a shape of the light emitting area defined in each of the first pixels PX11, PX12, and PX13 may be different from an arrangement rule of the second pixels PX21, PX22, and PX23 arranged in the second area A2 or a shape of the light emitting area defined in each of the second pixels PX21, PX22, and PX23.

In an embodiment, for example, the number of first pixels PX11, PX12, and PX13 arranged in a reference area in the first area A1 may be less than the number of second pixels PX21, PX22, and PX23 arranged in the reference area in the second area A2. Alternatively, areas of the first pixels PX11, PX12, and PX13 arranged in the reference area in the first area A1 may be less than areas of the second pixels PX21, PX22, and PX23 arranged in the reference area in the second area A2. Thus, the resolution of the first area A1 may be less than the resolution of the second area A2. Thus, when the same luminance is implemented within the reference area, a size of each of the first pixels PX11, PX12, and PX13 that should emit relatively bright lights is provided greater than a size of each of the second pixels PX21, PX22, and PX23, and thus lifespans of the first pixels PX11, PX12, and PX13 may be compensated for.

However, this is illustrated as an example, and in the display panel according to an embodiment of the disclosure, the first pixels PX11, PX12, and PX13 and the second pixels PX21, PX22, and PX23 may have a same shape as each other or be arranged based on a same arrangement rule as each other, but the disclosure is not limited to an embodiment.

FIG. 7A is a cross-sectional view illustrating a first area of the display panel according to an embodiment of the disclosure. FIG. 7B is a cross-sectional view illustrating a second area of the display panel according to an embodiment of the disclosure.

Referring to FIGS. 7A and 7B, in an embodiment, the display panel DP may include the display layer 100, the sensor layer 200, and a reflection preventing (or antireflection) layer 300. The display layer 100 may include a base layer 110, a barrier layer 120, a circuit layer 130, an element layer 140, and an encapsulation layer 150.

The base layer 110 may include first to fourth sub-base layers 111, 112, 113, and 114.

Each of the first sub-base layer 111 and the fourth sub-base layer 114 may include at least one selected from a polyimide-based resin, an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. In the disclosure, a “˜˜ based” resin means a resin containing a functional group of “˜˜”. In an embodiment, for example, each of the first and fourth sub-base layers 111 and 114 may include a polyimide.

Each of the second sub-base layer 112 and the third sub-base layer 113 may include an inorganic material. In an embodiment, for example, each of the second sub-base layer 112 and the third sub-base layer 113 may include at least one selected from a silicon oxide, a silicon nitride, a silicon oxy nitride, and an amorphous silicon. In an embodiment, for example, the second sub-base layer 112 may include a silicon oxy nitride, and the third sub-base layer 113 may include a silicon oxide.

A thickness of the first sub-base layer 111 may be greater than a thickness of the fourth sub-base layer 114, but the disclosure is not particularly limited thereto. A thickness of the second sub-base layer 112 may be less than a thickness of the third sub-base layer 113, but the disclosure is not particularly limited thereto.

The barrier layer 120 may be disposed on the base layer 110. The barrier layer 120 may include a plurality of sub-barrier layers 121, 122, 123, 124, and 125, the first lower light shielding layer BML1, and the second lower light shielding layer BML2.

The first and second lower light shielding layers BML1 and BML2 may be referred to as first and second lower layers, first and second lower metal layers, first and second lower electrode layers, first and second lower shielding layers, first and second light shielding layers, first and second metal layers, first and second electrode layers, first and second shielding layers, or first and second overlapping layers.

The plurality of sub-barrier layers 121, 122, 123, 124, and 125 may include the first sub-barrier layer 121, the second sub-barrier layer 122, the third sub-barrier layer 123, the fourth sub-barrier layer 124, and the fifth sub-barrier layer 125 that are sequentially laminated in a direction away from the base layer 110. Each of the first to fifth sub-barrier layers 121, 122, 123, 124, and 125 may include an inorganic material. In an embodiment, for example, each of the first to fifth sub-barrier layers 121, 122, 123, 124, and 125 may include at least one selected from a silicon oxide, a silicon nitride, a silicon oxy nitride, and an amorphous silicon. In an embodiment, for example, the first sub-barrier layer 121 may include a silicon oxy nitride, the second sub-barrier layer 122 may include a silicon oxide, the third sub-barrier layer 123 may include an amorphous silicon, the fourth sub-barrier layer 124 may include a silicon oxide, and the fifth sub-barrier layer 125 may include a silicon oxide.

Among the first to fifth sub-barrier layers 121, 122, 123, 124, and 125, the fifth sub-barrier layer 125 is closest to the circuit layer 130. The fifth sub-barrier layer 125 may be referred to as an upper sub-barrier layer. A thickness STK1 of the fifth sub-barrier layer 125 may be greater than a thickness of each of the first to fourth sub-barrier layers 121, 122, 123, and 124. In an embodiment, for example, the thickness STK1 of the fifth sub-barrier layer 125 may be greater than a sum of thicknesses STK2 of the first to fourth sub-barrier layers 121, 122, 123, and 124.

The first lower light shielding layer BML1 may be disposed on the first area A1, and the second lower light shielding layer BML2 may be disposed on the second area A2. The first lower light shielding layer BML1 and the second lower light shielding layer BML2 may be electrically insulated from each other, and different signals may be applied to the first lower light shielding layer BML1 and the second lower light shielding layer BML2. In an embodiment, for example, a constant voltage having a predetermined voltage level may be applied to the first lower light shielding layer BML1, and the first driving voltage ELVDD (see FIG. 5) provided to the pixel circuit PDC (see FIG. 5) may be provided to the second lower light shielding layer BML2.

The first lower light shielding layer BML1 and the second lower light shielding layer BML2 may be arranged on the same layer and may include the same material. In an embodiment, for example, the first lower light shielding layer BML1 and the second lower light shielding layer BML2 may be arranged between the fourth sub-barrier layer 124 and the fifth sub-barrier layer 125. The first lower light shielding layer BML1 and the second lower light shielding layer BML2 may be covered by the fifth sub-barrier layer 125. In such an embodiment, the fifth sub-barrier layer 125 among the first to fifth sub-barrier layers 121, 122, 123, 124, and 125 has the largest thickness, such that a degree to which characteristics of transistors are changed due to voltages provided to the first and second lower light shielding layers BML1 and BML2 may be substantially decreased.

The first lower light shielding layer BML1 may be provided with a first opening BMop that defines the transmissive area TP. The first lower light shielding layer BML1 may be a pattern that functions as a mask when an electrode opening CEop is formed in a common electrode CE. In an embodiment, for example, a light radiated from a rear surface of the base layer 110 toward the common electrode CE may pass through the first opening BMop of the first lower light shielding layer BML1 and reach portions of the common electrode CE and a capping layer CPL. That is, the portions of the common electrode CE and the capping layer CPL may be removed by the light passing through the first opening BMop of the first lower light shielding layer BML1. The light may be a laser beam.

An area of the first area A1, which overlaps the first opening BMop of the first lower light shielding layer BML1 in the third direction DR3, may be defined as the transmissive area TP, and the other area thereof may be defined as an element area EP. The plurality of first pixels PX11, PX12, and PX13 (see FIG. 6A) may be arranged in the element area EP, and the plurality of first pixels PX11, PX12, and PX13 may be spaced apart from the transmissive area TP.

A buffer layer BFL may be disposed on the barrier layer 120. The buffer layer BFL may be provided in both the first area A1 and the second area A2. The buffer layer BFL may effectively prevent metal atoms or impurities from being diffused from the base layer 110 to a first semiconductor pattern. Further, the buffer layer BFL may adjust a heat supply rate during a crystallization process for forming the first semiconductor pattern, such that the first semiconductor pattern may be uniformly formed.

The buffer layer BFL may include a plurality of inorganic layers. In an embodiment, for example, the buffer layer BFL may include a first sub-buffer layer including a silicon nitride and a second sub-buffer layer disposed on the first sub-buffer layer and including a silicon oxide. In an embodiment, as shown in FIG. 7A, the buffer layer BFL may partially overlap the transmissive area TP. In another embodiment, the buffer layer BFL may not overlap the transmissive area TP. That is, an opening corresponding to the transmissive area TP may be defined in the buffer layer BFL. In such an embodiment, as the buffer layer BFL is not provided in the transmissive area TP, transmittance of the transmissive area TP may be further improved.

The circuit layer 130 may be disposed on the buffer layer BFL, and the element layer 140 may be disposed on the circuit layer 130.

Referring to FIG. 7A, a silicon thin film transistor S-TFT and an oxide thin film transistor O-TFT of a first pixel circuit PDC1a are illustratively illustrated. The silicon thin film transistor S-TFT shown in FIG. 7A may be one of the first, second, fifth, sixth, and seventh transistors T1, T2, T5, T6, and T7 described in FIG. 5, and the oxide thin film transistor O-TFT shown in FIG. 7A may be one of the third and fourth transistors T3 and T4. In an embodiment, for example, the silicon thin film transistor S-TFT may be a first driving transistor T1-1 included in the first pixel circuit PDC1a.

The first to seventh transistors T1, T2, T3, T4, T5, T6, and T7 included in the first pixel circuit PDC1a may be referred to as first-type transistors. In the first area A1, the first lower light shielding layer BML1 may overlap all of the first-type transistors. That is, the first lower light shielding layer BML1 may completely overlap an area in which the first pixel circuit PDC1a is disposed. Thus, the voltage provided to the first lower light shielding layer BML1 may be provided regardless of an operation of the first pixel circuit PDC1a.

Referring to FIG. 7B, a silicon thin film transistor S-TFTa and an oxide thin film transistor O-TFTa of a second pixel circuit PDC2 are illustratively illustrated. The silicon thin film transistor S-TFTa shown in FIG. 7B may be the first transistor T1 described in FIG. 5, and the oxide thin film transistor O-TFTa shown in FIG. 7B may be one of the third and fourth transistors T3 and T4. In an embodiment, for example, the silicon thin film transistor S-TFTa may be a second driving transistor T1-2 included in the second pixel circuit PDC2.

The first to seventh transistors T1, T2, T3, T4, T5, T6, and T7 included in the second pixel circuit PDC2 may be referred to as second-type transistors. In the second area A2, the second lower light shielding layer BML2 may overlap some of the second-type transistors and may not overlap the others thereof. In an embodiment, for example, the second lower light shielding layer BML2 may overlap a portion of an area in which the second pixel circuit PDC2 is disposed and may particularly overlap the second driving transistor T1-2. Thus, the voltage provided to the second lower light shielding layer BML2 may be provided in synchronization with an operation of the second pixel circuit PDC2.

FIGS. 7A and 7B merely illustrate a portion of the first semiconductor pattern disposed on the buffer layer BFL, and the first semiconductor pattern may be further disposed in other areas. The first semiconductor pattern may be disposed in a specific rule across the pixels. The first semiconductor pattern may have a different electrical property depending on whether the first semiconductor pattern is doped. The first semiconductor pattern may include a first area having high conductivity and a second area having low conductivity. The first area may be doped with an N-type dopant or a P-type dopant. A P-type transistor may include a doped area doped with the P-type dopant, and an N-type transistor may include a doped area doped with the N-type dopant. The second area may be a non-doped area or may be an area doped at a concentration that is lower than a concentration of the first area.

A conductivity of the first area is greater than a conductivity of the second area, and the first area may substantially serve as an electrode or a signal line. The second area may substantially correspond to an active area (or a channel) of a transistor. In other words, a portion of the semiconductor pattern may be an active area of the transistor, another portion of the semiconductor pattern may be a source area or a drain area of the transistor, and still another portion of the semiconductor pattern may be a connection electrode or a connection signal line.

A source area SE1, an active area AC1, and a drain area DE1 of the silicon thin film transistor S-TFT or S-TFTa may be formed from (or defined by portions of) the first semiconductor pattern. The source area SE1 and the drain area DE1 may extend from the active area AC1 in opposite directions on a cross section.

FIG. 7B illustrates a portion of a connection signal line CSL formed from the first semiconductor pattern. The connection signal line CSL may be electrically connected to the sixth transistor T6 (see FIG. 5) and the seventh transistor T7 (see FIG. 5).

The circuit layer 130 may include a plurality of inorganic layers and a plurality of organic layers. In an embodiment, first to fifth insulating layers 10, 20, 30, 40, and 50 sequentially laminated on the buffer layer BFL may be inorganic layers, and sixth to eighth insulating layers 60, 70, and 80 may be organic layers.

The first insulating layer 10 may be disposed on the buffer layer BFL. The first insulating layer 10 may cover the first semiconductor pattern. The first insulating layer 10 may be an inorganic layer and/or an organic layer and may have a single-layer structure or a multi-layer structure. The first insulating layer 10 may include at least one selected from an aluminum oxide, a titanium oxide, a silicon oxide, a silicon nitride, a silicon oxy nitride, a zirconium oxide, and a hafnium oxide. In an embodiment, the first insulating layer 10 may be a single-layer silicon oxide layer. An insulating layer of the circuit layer 130, which will be described below, as well as the first insulating layer 10 may have a single-layer structure or a multi-layer structure.

A gate electrode GT1 of the silicon thin film transistor S-TFT or S-TFTa is disposed on the first insulating layer 10. The gate electrode GT1 may be a portion of a metal pattern. The gate electrode GT1 overlaps the active area AC1. In a process of doping the first semiconductor pattern, the gate electrode GT1 may function as a mask. The gate electrode GT1 may include titanium, silver, an alloy including silver, molybdenum, an alloy including molybdenum, aluminum, an alloy including aluminum, aluminum nitride, tungsten, tungsten nitride, copper, indium tin oxide, indium zinc oxide, or the like, but the disclosure is not particularly limited thereto.

The second insulating layer 20 may be disposed on the first insulating layer 10 to cover the gate electrode GT1. The second insulating layer 20 may be an inorganic layer and may have a single-layer structure or a multi-layer structure. The second insulating layer 20 may include at least one selected from a silicon oxide, a silicon nitride, and a silicon oxy nitride. In an embodiment, the second insulating layer 20 may have a single-layer structure including a silicon nitride layer.

The third insulating layer 30 may be disposed on the second insulating layer 20. The third insulating layer 30 may be an inorganic layer and may have a single-layer structure or a multi-layer structure. In an embodiment, for example, the third insulating layer 30 may have a multi-layer structure including a silicon oxide layer and a silicon nitride layer. One electrode Csta of the first capacitor Cst (see FIG. 5) may be disposed between the second insulating layer 20 and the third insulating layer 30. Further, the other one electrode of the first capacitor Cst may be disposed between the first insulating layer 10 and the second insulating layer 20.

A second semiconductor pattern may be disposed on the third insulating layer 30. The second semiconductor pattern may include an oxide semiconductor. The oxide semiconductor may include a plurality of areas that are classified according to whether a metal oxide is reduced. An area (hereinafter, referred to as a reduced area), in which the metal oxide is reduced, has higher conductivity than that of an area (hereinafter, a non-reduced area), in which the metal oxide is not reduced. The reduced area substantially serves as the source area/drain area of the transistor or the signal line. The non-reduced area substantially corresponds to the active area (or a semiconductor area or the channel) of the transistor. In other words, a portion of the second semiconductor pattern may be the active area of the transistor, another portion thereof may be the source area/drain area of the transistor, and still another portion thereof may be a signal transmitting area.

A source area SE2, an active area AC2, and a drain area DE2 of the oxide thin film transistor O-TFT or O-TFTa may be formed from (or defined by portions of) the second semiconductor pattern. The source area SE2 and the drain area DE2 may extend from the active area AC2 in opposite directions on a cross section.

The oxide thin film transistor O-TFT disposed in the first area A1 may overlap the first lower light shielding layer BML1. Thus, a light input from a lower side of the display panel DP is shielded by the first lower light shielding layer BML1 and thus may not be provided to the active area AC2 of the oxide thin film transistor O-TFT.

The oxide thin film transistor O-TFTa disposed in the second area A2 may not overlap the second lower light shielding layer BML2. Thus, a layer for shielding a light from a lower side of the oxide thin film transistor O-TFTa may be added. In an embodiment, for example, a third lower light shielding layer BML3 may be disposed under the oxide thin film transistor O-TFTa disposed in the second area A2. The third lower light shielding layer BML3 may be disposed between the second insulating layer 20 and the third insulating layer 30. The third lower light shielding layer BML3 may include a same material as that of the one electrode Csta of the first capacitor Cst (see FIG. 5) and the third lower light shielding layer BML3 and the one electrode Csta of the first capacitor Cst (see FIG. 5) may be formed through a same process.

The fourth insulating layer 40 may be disposed on the third insulating layer 30. The fourth insulating layer 40 may cover the second semiconductor pattern. The fourth insulating layer 40 may be an inorganic layer and may have a single-layer structure or a multi-layer structure. The fourth insulating layer 40 may include at least one selected from an aluminum oxide, a titanium oxide, a silicon oxide, a silicon nitride, a silicon oxy nitride, a zirconium oxide, and a hafnium oxide. In an embodiment, the fourth insulating layer 40 may have a single-layer structure containing a silicon oxide.

A gate electrode GT2 of the oxide thin film transistor O-TFT or O-TFTa is disposed on the fourth insulating layer 40. The gate electrode GT2 may be a portion of a metal pattern. The gate electrode GT2 overlaps the active area AC2. In a process of reducing the second semiconductor pattern, the gate electrode GT2 may function as a mask.

The fifth insulating layer 50 may be disposed on the fourth insulating layer 40 to cover the gate electrode GT2. The fifth insulating layer 50 may be an inorganic layer and/or an organic layer and may have a single-layer structure or a multi-layer structure. In an embodiment, for example, the fifth insulating layer 50 may have a multi-layer structure including a silicon oxide layer and a silicon nitride layer.

A first connection electrode CNE10 may be disposed on the fifth insulating layer 50. The first connection electrode CNE10 may be connected to the connection signal line CSL through a first contact hole CH1 defined or formed through the first to fifth insulating layers 10, 20, 30, 40, and 50.

A second opening ILop may be defined in the buffer layer BFL included in the circuit layer 130 and at least some insulating layers among the plurality of insulating layers 10, 20, 30, 40, 50, 60, 70, and 80. In an embodiment, for example, the second opening ILop may be defined in the buffer layer BFL and the first to fifth insulating layers 10, 20, 30, 40, and 50. The second opening ILop may be defined in an area that overlaps the transmissive area TP. That is, portions of the buffer layer BFL and the first to fifth insulating layers 10, 20, 30, 40, and 50, which overlap the transmissive area TP, are removed, and thus the transmittance of the transmissive area TP may be improved.

A minimum width of the second opening ILop may be less than a minimum width of the first opening BMop. Side walls of the buffer layer BFL and the first to fifth insulating layers 10, 20, 30, 40, and 50, which define the second opening ILop, may protrude toward the transmissive area TP further than a side wall of the first lower light shielding layer BML1.

The sixth insulating layer 60 may be disposed on the fifth insulating layer 50. The sixth insulating layer 60 may include an organic material, and the sixth insulating layer 60 may include a polyimide-based resin. In an embodiment, for example, the sixth insulating layer 60 may include a photosensitive polyimide. A second connection electrode CNE20 may be disposed on the sixth insulating layer 60. The second connection electrode CNE20 may be connected to the first connection electrode CNE10 through a second contact hole CH2 defined or formed through the sixth insulating layer 60.

The sixth insulating layer 60 may be disposed on both the element area EP and the transmissive area TP. The sixth insulating layer 60 may be referred to as a common organic layer. The sixth insulating layer 60 may fill a portion in which the second opening ILop is defined. That is, the sixth insulating layer 60 may overlap the transmissive area TP. As the sixth insulating layer 60 is provided in the transmissive area TP, a step of an upper surface of the sixth insulating layer 60 may be reduced. In such an embodiment, a step between layers overlapping the transmissive area TP is reduced, such that diffraction of a light input into the transmissive area TP may be alleviated (or reduced). Thus, deformation of the image due to the diffraction is reduced, and thus quality of the image acquired by the camera module CMM (see FIG. 2A) may be improved.

A portion of a preliminary common organic layer 60-P disposed in the transmissive area TP in a thickness direction may be removed in a way such that the sixth insulating layer 60 may be formed (or provided). In FIG. 7A, the preliminary common organic layer 60-P is illustrated with a dotted line, and a removed portion 60-del is indicated with dark hatching. A halftone mask may be used to form the sixth insulating layer 60 from the preliminary common organic layer 60-P.

A first thickness TK1 of the sixth insulating layer 60 in the transmissive area TP may be less than a second thickness TK2 of the sixth insulating layer 60 in the element area EP. In an embodiment, for example, the first thickness TK1 may be a minimum thickness or an average thickness of the sixth insulating layer 60 in the transmissive area TP, and the second thickness TK2 may be a maximum thickness or an average thickness of the sixth insulating layer 60 in the element area EP. The first thickness TK1 may be 40% or greater and less than 100% of the second thickness TK2. As a difference between the first thickness TK1 and the second thickness TK2 is increased, the step of the upper surface of the sixth insulating layer 60 may be increased. In this case, in a process of patterning a conductive layer closest to the transmissive area TP, the conductive layer may be further patterned (or further removed) as compared to a design. That is, the probability that a line (or a wiring line) becomes thinner may be increased, and accordingly, the probability that defects occur may also be increased. In an embodiment of the disclosure, as described above, the first thickness TK1 is provided to be 40% or greater of the second thickness TK2, such that the probability that defects occur may be decreased. Thus, the first thickness TK1 is provided to be 40% or greater of the second thickness TK2, and thus the transmittance of the transmissive area TP may be improved, and side effects resulting therefrom may be minimized.

In an embodiment, for example, where the second thickness TK2 is about 15,000 angstrom (Å), the first thickness TK1 may be about 6,000 Å or greater and about 10,000 Å or less. In this case, if the first thickness TK1 is greater than about 10,000 Å, a transmittance improving effect may be reduced. Thus, in such an embodiment, the first thickness TK1 may be determined within a range of 40% or greater of the second thickness TK2 and about 10,000 Å or less.

The seventh insulating layer 70 may be disposed on the sixth insulating layer 60 to cover the second connection electrode CNE20. The eighth insulating layer 80 may be disposed on the seventh insulating layer 70.

Each of the sixth insulating layer 60, the seventh insulating layer 70, and the eighth insulating layer 80 may be an organic layer. In the disclosure, the sixth insulating layer 60 may be referred to as a first organic insulating layer, the seventh insulating layer 70 may be referred to as a second organic insulating layer, and the eighth insulating layer 80 may be referred to as a third organic insulating layer. In an embodiment, for example, each of the sixth insulating layer 60, the seventh insulating layer 70, and the eighth insulating layer 80 may include a general purpose polymer such as benzocyclobutene (BCB), polyimide, hexamethyldisiloxane (HMDSO), polymethylmethacrylate (PMMA), and polystyrene (PS), a polymer derivative having a phenolic group, an acryl-based polymer, an imide-based polymer, an arylether-based polymer, an amide-based polymer, a fluorine-based polymer, a p-xylene-based polymer, a vinyl alcohol-based polymer, or blends thereof.

Referring to FIGS. 7A and 7B, the element layer 140 may be disposed on the circuit layer 130. Each of a first light emitting element ED1 and a second area light emitting element ED2a2 may include a pixel electrode AE (or an anode or a first electrode), a first functional layer HFL, a light emitting layer EL, a second functional layer EFL, and the common electrode CE (or a cathode or a second electrode). Each of a second light emitting element ED2a may include a connection pixel electrode AE-1, the first functional layer HFL, the light emitting layer EL, the second functional layer EFL, and the common electrode CE (or a cathode). The first functional layer HFL, the second functional layer EFL, and the common electrode CE may be commonly provided in the pixels PX (see FIG. 4).

The pixel electrode AE may be disposed on the eighth insulating layer 80. The pixel electrode AE may be connected to the second connection electrode CNE20 through a third contact hole CH3 defined or formed through the seventh insulating layer 70 and the eighth insulating layer 80. The pixel electrode AE may be a transmissive electrode, a semi-transmissive electrode, or a reflective electrode. In an embodiment, the pixel electrode AE may include a reflective layer including or formed of silver, magnesium, aluminum, platinum, palladium, gold, nickel, neodymium, iridium, chromium, or a compound thereof, and a transparent or semitransparent electrode layer formed on the reflective layer. The transparent or semitransparent electrode layer may include at least one selected from an indium tin oxide, an indium zinc oxide, an indium gallium zinc oxide, a zinc oxide or an indium oxide, and an aluminum-doped zinc oxide. In an embodiment, for example, the pixel electrode AE may have a multi-layer structure in which an indium tin oxide, silver, and an indium tin oxide are sequentially laminated.

The pixel defining layer PDL may be disposed on the eighth insulating layer 80. The pixel defining layer PDL may have a property of absorbing a light. In an embodiment, for example, the pixel defining layer PDL may have a black color. The pixel defining layer PDL may include a black coloring agent. The black coloring agent may include black dye and black pigment. The black coloring agent may include carbon black, a metal such as chromium, or an oxide thereof.

The opening PDLop through which a portion of the pixel electrode AE is exposed may be defined in the pixel defining layer PDL. That is, the pixel defining layer PDL may cover an edge of the pixel electrode AE. Further, the pixel defining layer PDL may cover a side surface of the eighth insulating layer 80, which is adjacent to the transmissive area TP. The pixel defining layer PDL may be spaced apart from a side surface of the seventh insulating layer 70, which is adjacent to the transmissive area TP. Thus, the pixel defining layer PDL may be stably in contact with the seventh insulating layer 70 and the eighth insulating layer 80.

Light emitting areas may be defined by the openings PDLop defined in the pixel defining layer PDL. The openings PDLop may be referred to as a pixel defining openings. Lights generated by the first to third light emitting elements ED1, ED2, and ED3 may be displayed in an area defined by the openings PDLop.

A spacer HSPC may be disposed on the pixel defining layer PDL. A protrusion spacer SPC may be disposed on the spacer HSPC. The spacer HSPC and the protrusion spacer SPC may have an integral shape and may include or be formed of a same material as each other. In an embodiment, for example, the spacer HSPC and the protrusion spacer SPC may be formed by a halftone mask through a same process. However, this is merely an example, and the disclosure is not limited thereto. In an embodiment, for example, the spacer HSPC and the protrusion spacer SPC may include different materials and may be formed by separate processes.

The first functional layer HFL may be disposed on the pixel electrode AE, the pixel defining layer PDL, the spacer HSPC, and the protrusion spacer SPC. The first functional layer HFL may include a hole transport layer HTL, include a hole injection layer HIL, or include both the hole transport layer and the hole injection layer. The first functional layer HFL may be disposed on the entirety of the first area A1 and the second area A2.

The light emitting layer EL may be disposed on the first functional layer HFL and may be disposed in an area corresponding to the opening PDLop of the pixel defining layer PDL. The light emitting layer EL may include an organic material, an inorganic material, or an organic/inorganic material that emit a light having a predetermined color. The light emitting layer EL may be disposed in the first area A1 and the second area A2. The light emitting layer EL disposed in the first area A1 may be disposed in the element area EP except for the transmissive area TP.

The second functional layer EFL may be disposed on the first functional layer HFL and cover the light emitting layer EL. The second functional layer EFL may include an electron transport layer ETL, include an electron injection layer EIL, or include both the electron transport layer and the electron injection layer. The second functional layer EFL may be disposed on the entirety of the first area A1 and the second area A2.

The common electrode CE may be disposed on the second functional layer EFL. The common electrode CE may be disposed in the first area A1 and the second area A2. The electrode opening CEop that overlaps the first opening BMop may be defined in the common electrode CE. A minimum width of the electrode opening CEop may be greater than a minimum width of the first opening BMop of the first lower light shielding layer BML1.

The element layer 140 may further include the capping layer CPL disposed on the common electrode CE. The capping layer CPL may serve to improve light emitting efficiency by the principle of constructive interference. In an embodiment, for example, the capping layer CPL may include a material having a refractive index of about 1.6 or higher for a light having a wavelength of about 589 nanometers (nm). The capping layer CPL may be an organic capping layer including an organic material, an inorganic capping layer including an inorganic capping layer, or a composite capping layer including an organic material and an inorganic material. In an embodiment, for example, the capping layer CPL may include carbocyclic compounds, heterocyclic compounds, amine group-containing compounds, porphine derivatives, phthalocyanine derivatives, naphthalocyanine derivatives, alkali metal complexes, alkaline earth metals complexes, or any combination thereof. The carbocyclic compounds, the heterocyclic compounds and the amine group-containing compounds may be optionally substituted with substituents including O, N, S, Se, Si, F, Cl, Br, I, or any combination thereof.

A portion of the capping layer CPL, which overlaps the electrode opening CEop of the common electrode CE, may be removed. A portion of the capping layer CPL and a portion of the common electrode CE, which include a portion overlapping the transmissive area TP, are removed, and thus light transmittance of the transmissive area TP may be further improved.

The encapsulation layer 150 may be disposed on the element layer 140. The encapsulation layer 150 may include an inorganic layer 151, an organic layer 152, and an inorganic layer 153 that are sequentially laminated, and layers constituting the encapsulation layer 150 are not limited thereto.

The inorganic layers 151 and 153 may protect the element layer 140 from moisture and oxygen, and the organic layer 152 may protect the element layer 140 from foreign substances such as dust particles. The inorganic layers 151 and 153 may include a silicon nitride layer, a silicon oxy nitride layer, a silicon oxide layer, a titanium oxide layer, an aluminum oxide layer, or the like. The organic layer 152 may include an acryl-based organic layer, but the disclosure is not limited thereto.

The sensor layer 200 may be disposed on the display layer 100. The sensor layer 200 may be referred to as a sensor, an input sensing layer, or an input sensing panel. The sensor layer 200 may include a sensor base layer 210, a first sensor conductive layer 220, a sensor insulating layer 230, a second sensor conductive layer 240, and a sensor cover layer 250.

The sensor base layer 210 may be directly disposed on the display layer 100. The sensor base layer 210 may be an inorganic layer including at least one selected from a silicon nitride, a silicon oxy nitride, and a silicon oxide. Alternatively, the sensor base layer 210 may be an organic layer including an epoxy resin, an acrylic resin, or an imide-based resin. The sensor base layer 210 may have a single-layer structure or have a multi-layer structure in which layers are laminated in the third direction DR3.

Each of the first sensor conductive layer 220 and the second sensor conductive layer 240 may have a single-layer structure or have a multi-layer structure in which layers are laminated in the third direction DR3.

The conductive layer having a single-layer structure may include a metal layer or a transparent conductive layer. The metal layer may include molybdenum, silver, titanium, copper, aluminum, or alloys thereof. The transparent conductive layer may include a transparent conductive oxide such as an indium tin oxide, an indium zinc oxide, a zinc oxide, or an indium zinc tin oxide. In addition, the transparent conductive layer may include a conductive polymer such as poly(3,4-ethylenedioxythiophene) (PEDOT), metal nanowire, graphene, or the like.

The conductive layer having a multi-layer structure may include metal layers. The metal layers may have, for example, a three-layer structure of titanium/aluminum/titanium. The conductive layer having a multi-layer structure may include at least one metal layer and at least one transparent conductive layer.

The sensor insulating layer 230 may be disposed between the first sensor conductive layer 220 and the second sensor conductive layer 240. The sensor insulating layer 230 may include an inorganic film. The inorganic film may include at least one selected from an aluminum oxide, a titanium oxide, a silicon oxide, a silicon nitride, a silicon oxy nitride, a zirconium oxide, and a hafnium oxide.

Alternatively, the sensor insulating layer 230 may include an organic film. The organic film may include at least one selected from an acryl-based resin, a methacrylate-based resin, a polyisoprene-based resin, a vinyl-based resin, an epoxy-based resin, a urethane-based resin, a cellulose-based resin, a siloxane-based resin, a polyimide-based resin, a polyamide-based resin, and a perylene-based resin.

The sensor cover layer 250 may be disposed on the sensor insulating layer 230 and cover the second sensor conductive layer 240. The second sensor conductive layer 240 may include a conductive pattern. The sensor cover layer 250 may cover the conductive pattern to reduce or eliminate a probability of causing damage to the conductive pattern in a subsequent process.

The sensor cover layer 250 may include an inorganic material. In an embodiment, for example, the sensor cover layer 250 may include a silicon nitride, but the disclosure is not particularly limited thereto.

The reflection preventing layer 300 may be disposed on the sensor layer 200. The reflection preventing layer 300 may include the division layer 310, a plurality of color filters 320, and a flattening layer 330. The division layer 310 and the color filters 320 are not arranged in the transmissive area TP of the first area A1.

The division layer 310 may be disposed to overlap the conductive pattern of the second sensor conductive layer 240. The sensor cover layer 250 may be disposed between the division layer 310 and the second sensor conductive layer 240. The division layer 310 may effectively prevent reflection of an external light by the second sensor conductive layer 240. A material constituting the division layer 310 is not particularly limited as long as the material absorbs a light. The division layer 310 is a layer having a black color. In an embodiment, for example, the division layer 310 may include a black coloring agent. The black coloring agent may include black dye and black pigment. The black coloring agent may include carbon black, a metal such as chromium, or an oxide thereof.

A plurality of division openings 310op1 and 310op2 and a transmissive opening 310opt may be defined in the division layer 310. The plurality of division openings 310op1 and 310op2 may overlap the plurality of light emitting layers EL, respectively. The color filters 320 may be arranged to correspond to the plurality of division openings 310op1 and 310op2. The color filter 320 may transmit a light provided from the light emitting layer EL overlapping the color filter 320.

The transmissive opening 310opt of the division layer 310 may overlap the first opening BMop of the first lower light shielding layer BML1. A minimum width of the transmissive opening 310opt of the division layer 310 may be substantially the same as a minimum width of the first opening BMop of the first lower light shielding layer BML1. That is, a distal end of the division layer 310 may be substantially aligned with a distal end of the first lower light shielding layer BML1 in an area adjacent to the transmissive area TP. In the disclosure, a state in which components are “substantially aligned” or widths or the like of the components are “substantially the same” includes a state in which the components are completely aligned or the widths or the like of the components have a same physical size as well as a state in which the components are the same within an error range that occurs in a process despite being identical in design.

The distal end of the division layer 310 may protrude toward the transmissive area TP further than a distal end of the pixel defining layer PDL and a distal end of the common electrode CE in an area adjacent to the transmissive area TP.

The flattening layer 330 may cover the division layer 310 and the color filters 320. The flattening layer 330 may include an organic material, and a flat surface may be provided on an upper surface of the flattening layer 330. In an embodiment, the flattening layer 330 may be omitted.

In an embodiment of the disclosure, the reflection preventing layer 300 may include a reflection adjusting layer instead of the color filters 320. In an embodiment, for example, in the display panel illustrated in FIGS. 7A and 7B, the color filters 320 may be omitted, and the reflection adjusting layer may be added in a place in which the color filters 320 are omitted. The reflection adjusting layer may selectively absorb a light in a partial band among a light reflected from an inside of the display panel and/or the electronic device or a light input from an outside of the display panel and/or the electronic device.

In an embodiment, for example, the reflection adjusting layer absorbs a light having a first wavelength area in a range of about 490 nm to about 505 nm and a light having a second wavelength area in a range of about 585 nm to about 600 nm, so that light transmittance in the first wavelength area and the second wavelength area may be 40% or less. The reflection adjusting layer may absorb a light having a wavelength deviating from wavelength ranges of a red light, a green light, and a blue light emitted from the light emitting layer EL. In this way, the reflection adjusting layer may absorb a light having a wavelength not belonging to the wavelength ranges of the red light, the green light, or the blue light emitted from the light emitting layer EL, thereby effectively preventing or substantially minimizing a decrease in luminance of the display panel and/or the electronic device. Further, at the same time, degradation of light emitting efficiency of the display panel and/or the electronic device may be prevented or minimized, and visibility may be improved.

The reflection adjusting layer may be provided as an organic material layer including dye, pigment, or a combination thereof. The reflection adjusting layer may include at least one selected from a tetraazaporphyrin (TAP)-based compound, a porphyrin-based compound, a metal porphyrin-based compound, an oxazine-based compound, a squarylium-based compound, a triarylmethane-based compound, a polymethine-based compound, a traquinone-based compound, a phthalocyanine-based compound, an azo-based compound, a perylene-based compound, an xanthene-based compound, a diimmonium-based compound, a dipyrromethene-based compound, a cyanine-based compound, and combinations thereof.

In an embodiment, the reflection adjusting layer may have a transmittance in a range of about 64% to about 72/%. The transmittance of the reflection adjusting layer may be adjusted depending on the content of pigment and/or dye contained in the reflection adjusting layer. The reflection adjusting layer may overlap the light emitting area in a plan view but may not overlap the transmissive area TP in a plan view.

FIG. 8A is a plan view illustrating a portion of a first lower light shielding layer according to an embodiment of the disclosure, and FIG. 8B is a plan view illustrating a portion of a second lower light shielding layer according to an embodiment of the disclosure.

In FIG. 8A, the first pixel unit PXU1 overlapping the first lower light shielding layer BML1 is illustrated as a dotted line, and in FIG. 8B, the first sub-pixel unit PXU2a overlapping the second lower light shielding layer BML2 is illustrated as a dotted line. An arrangement relationship between the second sub-pixel unit PXU2b (see FIG. 6) and the second lower light shielding layer BML2 is substantially the same as an arrangement relationship between the first sub-pixel unit PXU2a and the second lower light shielding layer BML2, and thus a description thereof will be omitted.

The first pixel unit PXU1 may include three first pixel circuits PDC1a, PDC1b, and PDC1c. The first sub-pixel unit PXU2a may include two second pixel circuits PDC2a and PDC2b. The dotted areas illustrated in FIGS. 8A and 8B may correspond to areas in which the three first pixel circuits PDC1a, PDC1b, and PDC1c and the two second pixel circuits PDC2a and PDC2b are arranged.

Referring to FIGS. 8A and 8B, the first lower light shielding layer BML1 and the second lower light shielding layer BML2 may be arranged in a same layer and may be formed simultaneously through a same process. As a result, as compared to a process of forming the first and second lower light shielding layers in different layers, in a process of forming the first and second lower light shielding layers BML1 and BML2 according to an embodiment, a mask process may be performed only once. Thus, the process of manufacturing the display panel DP (see FIG. 7A) may be simplified, and thus manufacturing costs of the display panel DP may be reduced.

The first lower light shielding layer BML1 and the second lower light shielding layer BML2 may be arranged between the fourth sub-barrier layer 124 and the fifth sub-barrier layer 125 as illustrated in FIGS. 7A and 7B.

The first lower light shielding layer BML1 and the second lower light shielding layer BML2 may be electrically insulated from each other. A constant voltage having a predetermined voltage level may be provided to the first lower light shielding layer BML1, and a power supply voltage provided to the second pixel circuit PDC2a or PDC2b may be provided to the second lower light shielding layer BML2. In an embodiment, for example, the first driving voltage ELVDD (see FIG. 5) may be provided to the second lower light shielding layer BML2.

In an embodiment, as shown in FIG. 8A, the first lower light shielding layer BML1 may overlap the entire area in which the first pixel unit PXU1 is disposed. Thus, the first lower light shielding layer BML1 may overlap first pixels PX1r, PX1g, and PX1b (see FIG. 6) included in the first pixel unit PXU1. In the first area A1, the first lower light shielding layer BML1 may overlap all of first-type transistors included in the first pixels PX1r, PX1g, and PX1b. Thus, the voltage provided to the first lower light shielding layer BML1 may be provided regardless of operations of the first pixels PX1r, PX1g, and PX1b.

In an embodiment, as shown in FIG. 8B, the second lower light shielding layer BML2 may overlap a portion of an area in which the first sub-pixel unit PXU2a is disposed. In an embodiment, for example, the first sub-pixel unit PXU2a may include a (2-2)^{th} color pixel PX2g (see FIG. 6) and a (2-3)^{th} color pixel PX2b (see FIG. 6). In the second area A2, the second lower light shielding layer BML2 may overlap some of second-type transistors included in the (2-2)^{th} color pixel PX2g and the (2-3)^{th} color pixel PX2b. In an embodiment, for example, the second lower light shielding layer BML2 may overlap the first transistor T1 (see FIG. 5). Thus, the voltage provided to the second lower light shielding layer BML2 may be provided in synchronization with operations of the (2-2)^{th} color pixel PX2g and the (2-3)^{th} color pixel PX2b.

Each of the first lower light shielding layer BML1 and the second lower light shielding layer BML2 may have a single-layer structure or a multi-layer structure including a plurality of layers. In an embodiment, for example, each of the first lower light shielding layer BML1 and the second lower light shielding layer BML2 may have a multi-layer structure in which titanium and molybdenum are sequentially laminated. A passage may be provided by cracks formed in the first to fourth sub-barrier layers 121, 122, 123, and 124 (see FIG. 7A) and particles between the first to fourth sub-barrier layers 121, 122, 123, and 124 (see FIG. 7A). In this case, hydrogen may flow in through the passage, and a lower layer including titanium may serve to adsorb the hydrogen. Thus, the probability that a defect occurs due to the hydrogen in the transistor may be reduced. In an embodiment of the disclosure, molybdenum may be substituted by copper. Alternatively, each of the first lower light shielding layer BML1 and the second lower light shielding layer BML2 may include molybdenum or copper, but the disclosure is not particularly limited thereto.

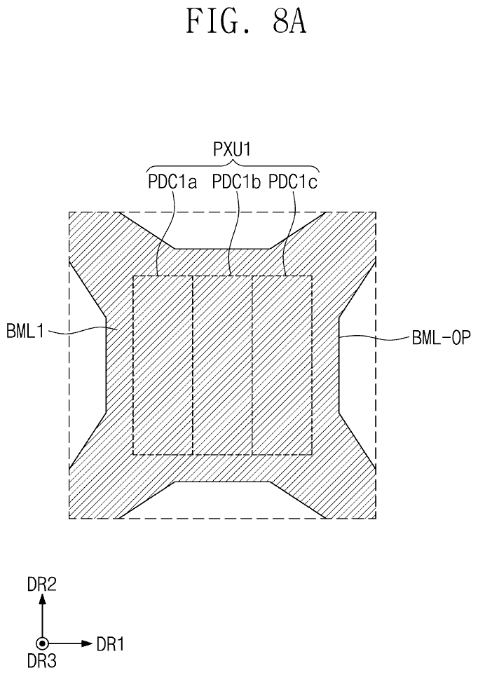

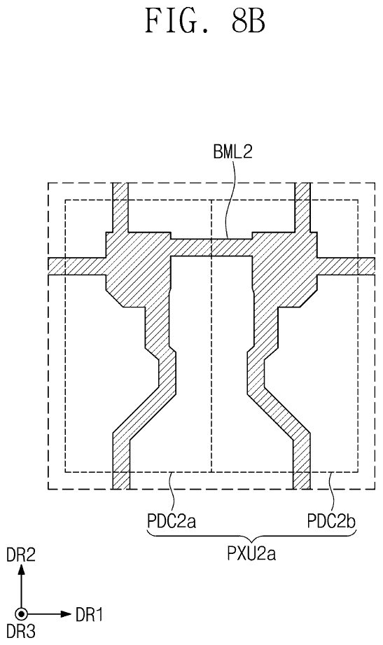

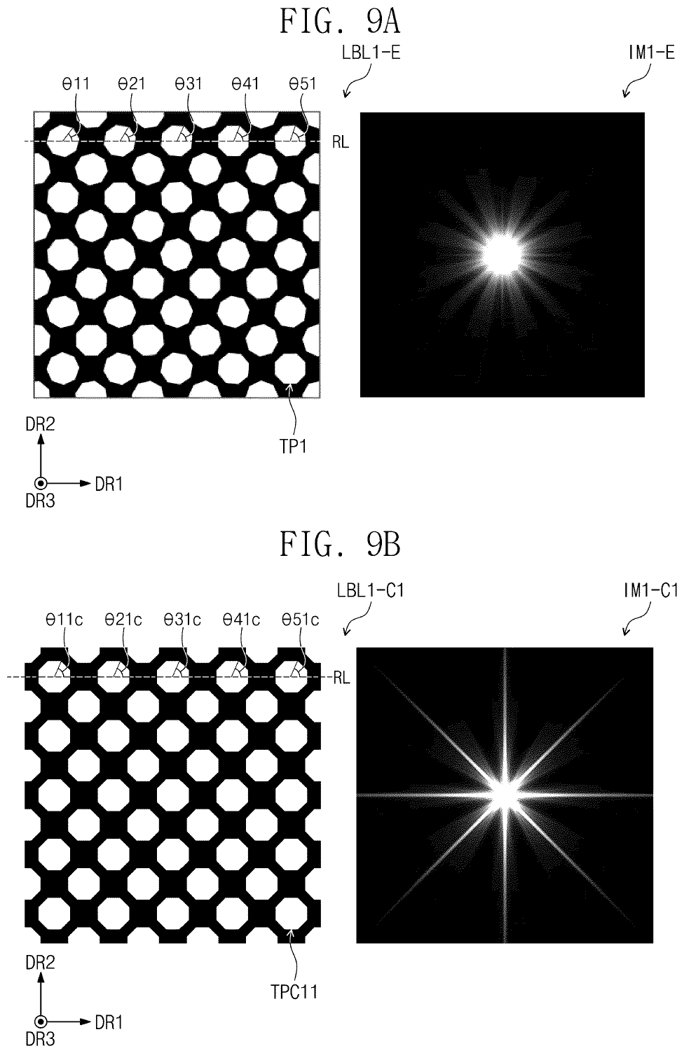

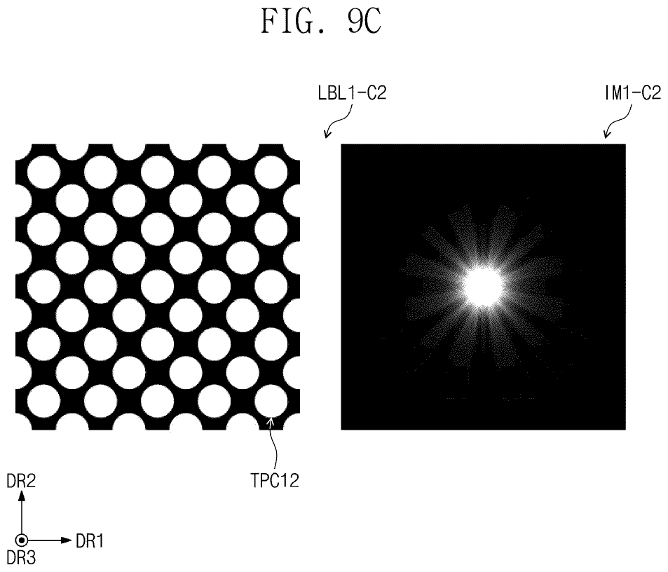

FIGS. 9A to 9C are views illustrating a light shielding layer of the first area and a light source image captured through the first area. FIG. 9A illustrates a light shielding layer LBL1-E and a light source image IM1-E according to an embodiment of the disclosure, FIG. 9B illustrates a light shielding layer LBL1-C1 and a light source image IM1-C1 according to a comparative embodiment, and FIG. 9C illustrates a light shielding layer LBL1-C2 and a light source image IM1-C2 according to a comparative embodiment.

The light shielding layer according to an embodiment of the disclosure may include a plurality of transmissive parts TP1, and shapes of the transmissive parts TP1 may include N different shapes. Hereinafter, the features of the transmissive parts TP1 described above may be commonly applied to the transmissive parts, which will be described below.

Each of the transmissive parts TP1 may have one shape selected from N different shapes. The N different shapes may include one reference shape and N−1 tilted shapes. Each of the tilted shapes may correspond to a shape obtained by rotating the reference shape by a predetermined tilt angle. That is, when the shape of one of the transmissive parts TP1 is referred to as the reference shape, the transmissive parts TP1 in the first area A1 may have the reference shape or a shape obtained by rotating the reference shape by a predetermined tilt angle.

The reference shape may be a shape other than a circle. In an embodiment, for example, the shape of each of the transmissive parts TP1 may be a shape having L vertices. The shape having L vertices may be an L-angular shape or may be an irregular shape in which at least one curved line and at least one straight line are mixed or combined.

The tilt angles may be different from each other by an angle of 360° or less and may be an integer multiple of a reference tilt angle. The reference tilt angle may be a minimum value among the tilt angles. The reference tilt angle may be a divisor (or a factor) of 360. That is, the reference tilt angle may be a value that is 360° when the value is multiplied by an integer.

The reference tilt angle within the first area A1 including M transmissive parts TP1 having N different shapes may be at least 360/N or less. M may be equal to or greater than N. That is, within the first area A1, there may be one reference shape or two or more reference shapes. The number of tilted shapes may be equal to or less than the number of reference shapes.

In an embodiment, within the first area A1, the N shapes may be arranged in a direction in which the tilt angle is increased in one direction. The one direction is not limited to any specific direction. In an embodiment, for example, the one direction may be a first direction, a second direction, or a third direction. Alternatively, the one direction may be a diagonal direction or a curved direction. Alternatively, the one direction may be a spiral direction or a zigzag direction. In such embodiments, the N shapes may be randomly arranged within the first area A1. In an embodiment, for example, among the N shapes, the same shapes may be arranged adjacent to each other, shapes having relatively small tilt angles may be arranged adjacent to each other, and shapes having relatively large tilt angles may be arranged adjacent to each other. Alternatively, shapes having tilt angles that are greatly different from each other may be arranged adjacent to each other. In the display panel according to an embodiment of the disclosure, an arrangement form may be variously changed as long as the numbers of the different shapes arranged in the first area A1 are similar to each other, but the disclosure is not limited to an embodiment.

In an embodiment, for example, the light shielding layer LBL1-E includes the plurality of transmissive parts TP1. The transmissive parts TP1 are spaced apart from each other. The transmissive parts TP1 may have shapes obtained by tilting one regular hexagonal shape by predetermined tilt angles. Because the transmissive parts TP1 have the shapes rotated by different tilt angles, positions of specific vertices of the transmissive parts may be tilted with respect to an imaginary reference line RL by different angles. In an embodiment, for example, angles θ11, θ21, θ31, θ41, and θ51 at which a second closest vertex is positioned with respect to the reference line RL may be different from each other, as shown in FIG. 9A. An angle difference between the angles θ11, θ21, θ31, θ41, and θ51 may be defined as the tilt angle described above. When the transmissive part in the leftmost first row is set as the reference shape, the transmissive parts sequentially arranged in the first direction DR1 have shapes tilted by about 5°. That is, the angle difference between the angles θ11, θ21, θ31, θ41, and θ51 is about 5° in the first direction DR1, and as a distance from the reference in the first direction DR1 is increased, the transmissive parts TP1 having a shape obtained by rotating the reference shape by about 5° in a clockwise direction, a shape obtained by rotating the reference shape by about 10° in a clockwise direction, a shape obtained by rotating the reference shape by about 15° in a clockwise direction, and a shape obtained by rotating the reference shape about by 20° in a clockwise direction may be arranged.

The embodiment described above is illustrated as an example, and in the display panel according to an embodiment of the disclosure, the arrangement of the transmissive parts TP1 defined in the light shielding layer LBL1-E may be variously changed. In an embodiment, for example, the transmissive parts TP1 may be arranged to have shapes tilted by about 5° with reference to an imaginary reference line in the second direction DR2. Alternatively, the transmissive parts TP1 may be arranged to have shapes tilted by about 5° with reference to an imaginary reference line in the diagonal direction. An arrangement form of the transmissive parts TP1 is not limited to an embodiment in which the imaginary reference line is linear, and the imaginary reference line may extend along another shape such as a spiral shape, a circular shape, an elliptic shape, and a random shape, and may be variously changed.

Referring to FIG. 9B, in the light shielding layer LBL1-C1 according to the comparative embodiment, shapes of all transmissive parts TPC may be the same as each other. That is, the transmissive parts TP1 (see FIG. 9A) according to an embodiment of the disclosure may be obtained by rotating/tilting a transmissive part TPC1 according to the comparative embodiment by different tilt angles. In the light shielding layer LBL1-C1 according to the comparative embodiment, angles θ11c, θ21c, θ31c, θ41c, and θ51c between transmissive parts arranged in a first row of the reference line RL may be the same as each other, and a tilt angle that is a difference between the angles θ11c, θ21c, θ31c, θ41c, and θ51c may be 0°.

The light source image IM1-C1 captured through the light shielding layer LBL1-C1 according to the comparative embodiment shown in FIG. 9B may noticeably exhibit a light splitting phenomenon (or a flare phenomenon) as compared to the light source image IM1-E captured through the light shielding layer LBL1-E according to an embodiment of the disclosure shown in FIG. 9A. Thus, in the display panel according to an embodiment of the disclosure, as the plurality of transmissive parts TP1 having different shapes through tilting at different angles are formed in the light shielding layer LBL1-C1, the light splitting phenomenon may be alleviated as compared to the light shielding layer LBL1-C1 having the transmissive parts TPC having the same shape. According to an embodiment of the disclosure, a phenomenon in which a light is diffracted in a specific direction may be alleviated by rotating the transmissive parts uniformly arranged in the same shape. Accordingly, a light leakage phenomenon or a light splitting phenomenon in a specific direction may be reduced, and distortion of the captured image may be reduced. Thus, the quality of the image captured through the first area A1 may be improved.

Referring to FIG. 9C, in the light shielding layer LBL1-C2 according to the comparative embodiment, each of transmissive parts TPC2 may have a circular shape. The light source image IM1-C2 captured through the light shielding layer LBL1-C2 according to the comparative embodiment shown in FIG. 9C is similar to the light source image IM1-E captured through the light shielding layer LBL1-E according to an embodiment of the disclosure shown in FIG. 9A. In a case where the transmissive parts TPC2 have a circular shape, a light is less diffracted in a specific direction and is dispersed uniformly, and thus the light splitting phenomenon may be improved as a whole. According to an embodiment of the disclosure, even when the transmissive parts TP1 are formed in a shape having vertices such as a polygonal shape or an irregular shape rather than a circular shape, the light shielding layer LBL1-E is formed by combining the transmissive parts TP1 having various shapes tilted at a predetermined tilt angle, and thus the transmissive area in which the light splitting phenomenon is improved may be provided. Thus, the transmissive area (first area) in which improved transmittance is secured and the degree of freedom in design of the transmissive parts TP1 is improved may be provided.

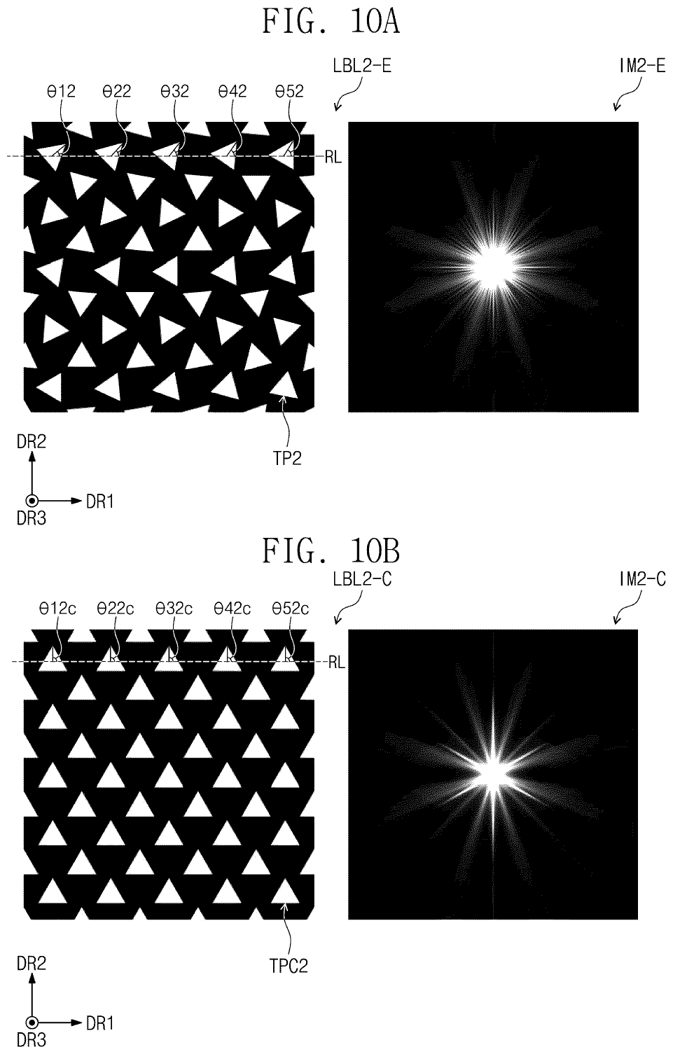

FIGS. 10A and 10B are views illustrating the light shielding layer of the first area and the light source image captured through the first area. FIG. 10A illustrates a light shielding layer LBL2-E and a light source image IM2-E according to an embodiment of the disclosure, and FIG. 10B illustrates a light shielding layer LBL2-C and a light source image IM2-C according to a comparative embodiment. Hereinafter, any repetitive detailed description of the same or like elements as those described above will be omitted.

Referring to FIG. 10A, in the light shielding layer LBL2-E according to an embodiment of the disclosure, transmissive parts TP2 may include N different shapes. The shapes of the transmissive parts TP2 may be shapes obtained by rotating the reference shape by predetermined tilt angles, and the tilt angles may be different from each other.

In an embodiment, where the transmissive parts TP2 are arranged in the first direction DR1 as an example, angles θ12, θ22, θ32, θ42, and θ52 at which vertices closest to the reference line RL are positioned may be different from each other. That is, the transmissive parts TP2 arranged in the first direction DR1 may have shapes obtained through rotation by different tilt angles.

Referring to FIG. 10B, in the light shielding layer LBL2-C according to the comparative embodiment, shapes of all of the transmissive parts TPC2 may be the same as each other. In an embodiment of the disclosure, the transmissive parts TP2 (see FIG. 10A) may be obtained by rotating/tilting the transmissive parts TPC2 according to the comparative embodiment by different tilt angles. In the light shielding layer LBL2-C according to the comparative embodiment, angles θ12c, θ22c, θ32c, θ42c, and θ52c between transmissive parts arranged in a first row of the reference line RL may be the same as each other, and a tilt angle that is a difference between the angles θ12c, θ22c, θ32c, θ42c, and θ52c may be 0°.

The light source image IM2-C captured through the light shielding layer LBL2-C according to the comparative embodiment shown in FIG. 10B may exhibit a relatively large light splitting phenomenon as compared to the light source image IM2-E captured through the light shielding layer LBL2-E according to an embodiment of the disclosure shown in FIG. 10A. In the display panel according to an embodiment of the disclosure, as the plurality of transmissive parts TP2 having different shapes through tilting at different angles are formed in the light shielding layer LBL2-C, the light splitting phenomenon may be alleviated as compared to the light shielding layer LBL2-C having the transmissive parts TPC2 having the same shape. According to an embodiment of the disclosure, the phenomenon in which the light is diffracted in a specific direction may be alleviated by rotating the transmissive parts uniformly arranged in the same shape. Accordingly, the light leakage phenomenon or the light splitting phenomenon in a specific direction may be reduced, and display characteristics in the first area A1 may be improved.

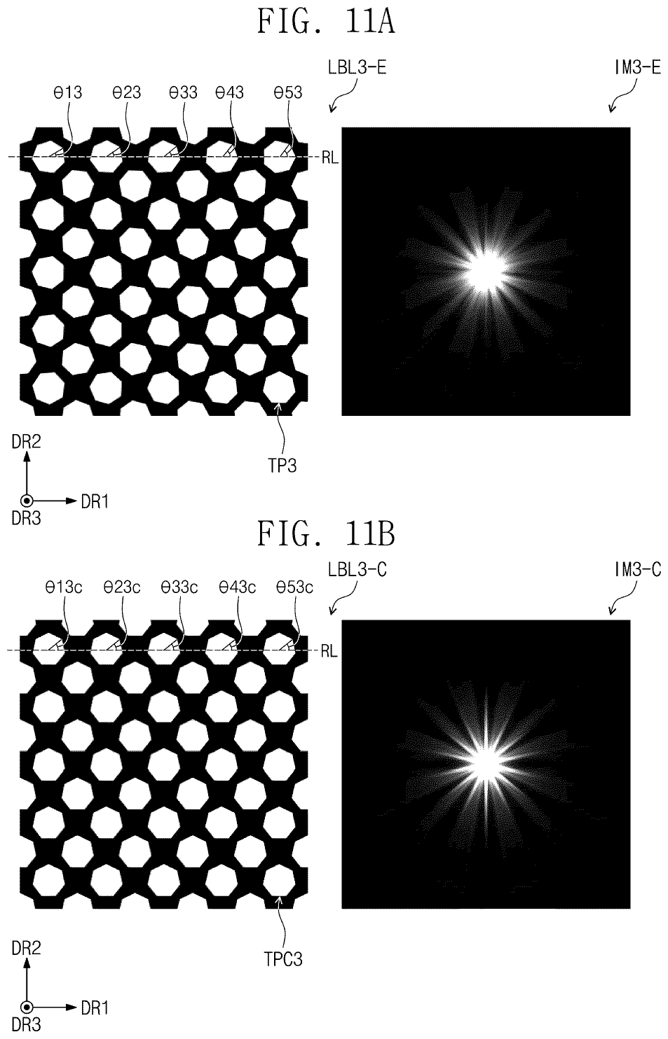

FIGS. 11A and 11B are views illustrating the light shielding layer of the first area and the light source image captured through the first area. FIG. 11A illustrates a light shielding layer LBL3-E and a light source image IM3-E according to an embodiment of the disclosure, and FIG. 11B illustrates a light shielding layer LBL3-C and a light source image IM3-C according to a comparative embodiment. Hereinafter, any repetitive detailed description of the same or like elements as those described above will be omitted.

Referring to FIG. 11A, in the light shielding layer LBL3-E according to an embodiment of the disclosure, transmissive parts TP3 may include N different triangular shapes. The shapes of the transmissive parts TP3 may be shapes obtained by rotating the reference shape by predetermined tilt angles, and the tilt angles may be different from each other.

In an embodiment, where the transmissive parts TP3 are arranged in the first direction DR1 as an example, angles θ13, θ23, θ33, θ43, and θ53 at which vertices closest to the reference line RL are positioned may be different from each other. That is, the transmissive parts TP3 arranged in the first direction DR1 may have shapes obtained through rotation by different tilt angles.

Referring to FIG. 11B, in the light shielding layer LBL3-C according to the comparative embodiment, shapes of all of transmissive parts TPC3 may be the same triangular shape. In an embodiment of the disclosure, the transmissive parts TP3 (see FIG. 11A) may be obtained by rotating/tilting the transmissive parts TPC3 according to the comparative embodiment by different tilt angles. In the light shielding layer LBL3-C according to the comparative embodiment, angles θ13c, θ23c, θ33c, θ43c, and θ53c between the transmissive parts arranged in the first row of the reference line RL may be the same as each other, and a tilt angle that is a difference between the angles θ13c, θ23c, θ33c, θ43c, and θ53c may be 0°.

The light source image IM3-C captured through the light shielding layer LBL3-C according to the comparative embodiment shown in FIG. 11B may exhibit a relatively large light splitting phenomenon as compared to the light source image IM3-E captured through the light shielding layer LBL3-E according to an embodiment of the disclosure shown in FIG. 11A. In the display panel according to an embodiment of the disclosure, as the plurality of transmissive parts TP3 having different shapes through tilting at different angles are formed in the light shielding layer LBL3-C, the light splitting phenomenon may be alleviated as compared to the light shielding layer LBL3-C having the transmissive parts TPC3 having the same shape. According to an embodiment of the disclosure, the phenomenon in which the light is diffracted in a specific direction may be alleviated by rotating the transmissive parts uniformly arranged in the same shape. Accordingly, the light leakage phenomenon or the light splitting phenomenon in a specific direction may be reduced, and display characteristics in the first area A1 may be improved.

FIGS. 12A and 12B are views illustrating the light shielding layer of the first area and the light source image captured through the first area. FIG. 12A illustrates a light shielding layer LBL4-E and a light source image IM4-E according to an embodiment of the disclosure, and FIG. 12B illustrates a light shielding layer LBL4-C and a light source image IM4-C according to a comparative embodiment. Hereinafter, any repetitive detailed description of the same or like elements as those described above will be omitted.

Referring to FIG. 12A, in the light shielding layer LBL4-E according to an embodiment of the disclosure, transmissive parts TP4 may include N different quadrangular shapes. The shapes of the transmissive parts TP4 may be shapes obtained by rotating the reference shape by predetermined tilt angles, and the tilt angles may be different from each other.

In an embodiment, where the transmissive parts TP4 are arranged in the first direction DR1 as an example, angles θ14, θ24, θ34, θ44, and θ54 at which vertices closest to the reference line RL are positioned may be different from each other. That is, the transmissive parts TP4 arranged in the first direction DR1 may have shapes obtained through rotation by different tilt angles.

Referring to FIG. 12B, in the light shielding layer LBL4-C according to the comparative embodiment, shapes of all of transmissive parts TPC4 may be the same quadrangular shape. That is, the transmissive parts TP4 (see FIG. 12A) according to an embodiment of the disclosure may be obtained by rotating/tilting the transmissive parts TPC4 according to the comparative embodiment by different tilt angles. In the light shielding layer LBL4-C according to the comparative embodiment, angles θ14c, θ24c, θ34c, θ44c, and θ54c between the transmissive parts arranged in the first row of the reference line RL may be the same as each other, and a tilt angle that is a difference between the angles θ14c, θ24c, θ34c, θ44c, and θ54c may be 0°.

The light source image IM4-C captured through the light shielding layer LBL4-C according to the comparative embodiment shown in FIG. 11B may exhibit a relatively large light splitting phenomenon as compared to the light source image IM4-E captured through the light shielding layer LBL4-E according to an embodiment of the disclosure shown FIG. 11A. In the display panel according to an embodiment of the disclosure, as the plurality of transmissive parts TP4 having different shapes through tilting at different angles are formed in the light shielding layer LBL4-C, the light splitting phenomenon may be alleviated as compared to the light shielding layer LBL4-C having the transmissive parts TPC4 having the same shape. According to an embodiment of the disclosure, the phenomenon in which the light is diffracted in a specific direction may be alleviated by rotating the transmissive parts uniformly arranged in the same shape. Accordingly, the light leakage phenomenon or the light splitting phenomenon in a specific direction may be reduced, and display characteristics in the first area A1 may be improved.

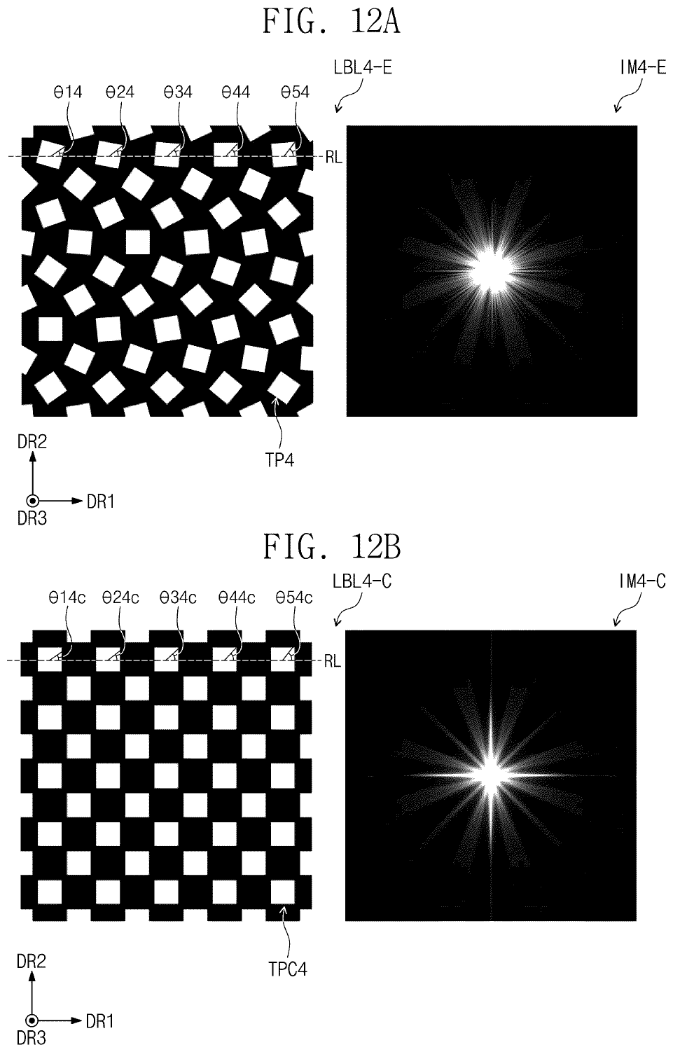

FIGS. 13A and 13B are views illustrating the light shielding layer of the first area and the light source image captured through the first area. FIG. 13A illustrates a light shielding layer LBL5-E and a light source image IM5-E according to an embodiment of the disclosure, and FIG. 13B illustrates a light shielding layer LBL5-C and a light source image IM5-C according to a comparative embodiment. Hereinafter, any repetitive detailed description of the same or like elements as those described above will be omitted.

Referring to FIG. 13A, in the light shielding layer LBL5-E according to an embodiment of the disclosure, transmissive parts TP5 may include N different decagonal shapes. The shapes of the transmissive parts TP5 may be shapes obtained by rotating the reference shape by predetermined tilt angles, and the tilt angles may be different from each other.

In an embodiment, where the transmissive parts TP5 are arranged in the first direction DR1 as an example, angles θ15, θ25, θ35, θ45, and θ55 at which vertices closest to the reference line RL are positioned may be different from each other. That is, the transmissive parts TP5 arranged in the first direction DR1 may have shapes obtained through rotation by different tilt angles.

Referring to FIG. 13B, in the light shielding layer LBL5-C according to the comparative embodiment, shapes of all of transmissive parts TPC5 may be the same decagonal shape. That is, the transmissive parts TP5 (see FIG. 13A) according to an embodiment of the disclosure may be obtained by rotating/tilting the transmissive parts TPC5 according to the comparative embodiment by different tilt angles. In the light shielding layer LBL5-C according to the comparative embodiment, angles θ15c, θ25c, θ35c, θ45c, and θ55c between the transmissive parts arranged in the first row of the reference line RL may be the same as each other, and a tilt angle that is a difference between the angles θ15c, θ25c, θ35c, θ45c, and θ55c may be 0°.

The light source image IM5-C captured through the light shielding layer LBL5-C according to the comparative embodiment shown in FIG. 13B may exhibit a relatively large light splitting phenomenon as compared to the light source image IM5-E captured through the light shielding layer LBL5-E according to an embodiment of the disclosure shown in FIG. 13A. In the display panel according to an embodiment of the disclosure, as the plurality of transmissive parts TP5 having different shapes through tilting at different angles are formed in the light shielding layer LBL5-C, the light splitting phenomenon may be alleviated as compared to the light shielding layer LBL5-C having the transmissive parts TPC5 having the same shape. According to an embodiment of the disclosure, the phenomenon in which the light is diffracted in a specific direction may be alleviated by rotating the transmissive parts uniformly arranged in the same shape. Accordingly, the light leakage phenomenon or the light splitting phenomenon in a specific direction may be reduced, and display characteristics in the first area A1 may be improved.

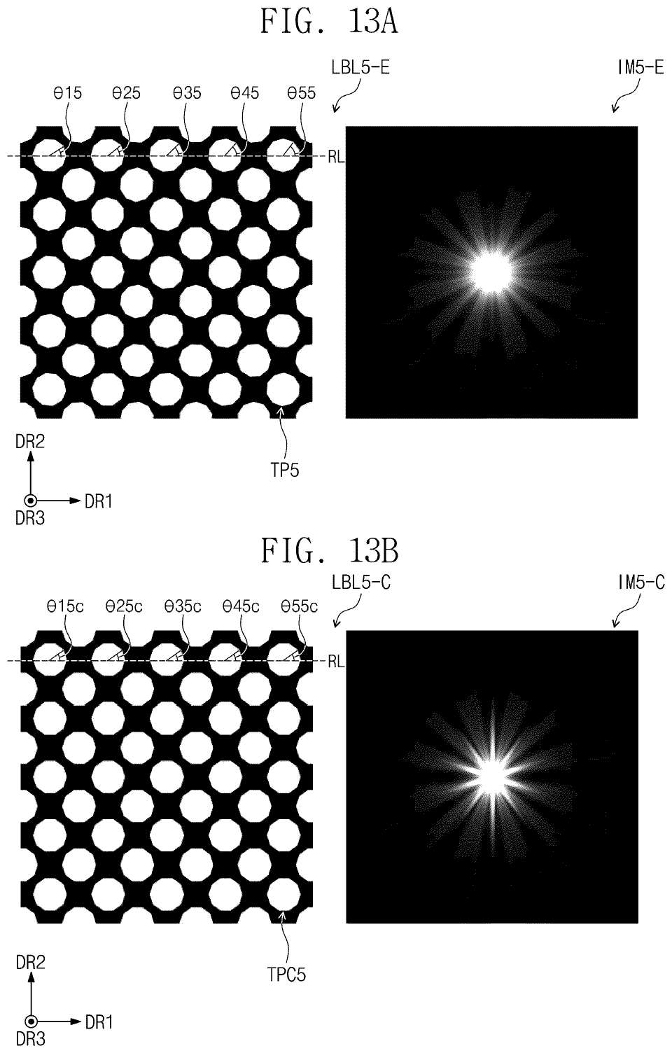

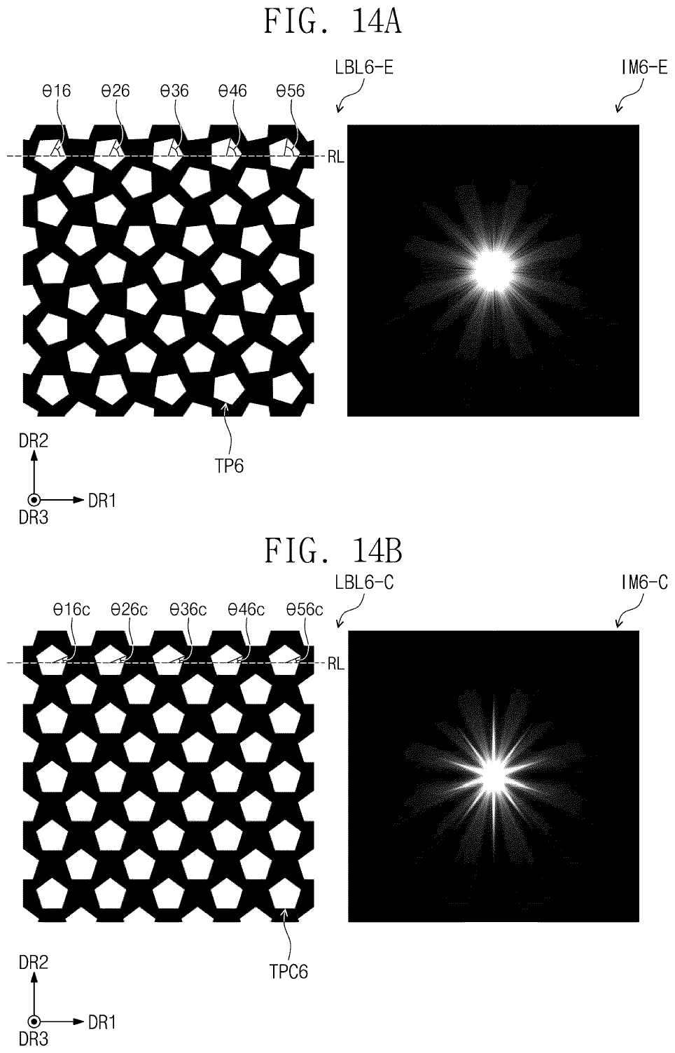

FIGS. 14A and 14B are views illustrating the light shielding layer of the first area and the light source image captured through the first area. FIG. 14A illustrates a light shielding layer LBL6-E and a light source image IM6-E according to an embodiment of the disclosure, and FIG. 14B illustrates a light shielding layer LBL6-C and a light source image IM6-C according to a comparative embodiment. Hereinafter, any repetitive detailed description of the same or like elements as those described above will be omitted.

Referring to FIG. 14A, in the light shielding layer LBL6-E according to an embodiment of the disclosure, transmissive parts TP6 may include N different pentagonal shapes. The shapes of the transmissive parts TP6 may be shapes obtained by rotating the reference shape by predetermined tilt angles, and the tilt angles may be different from each other.

In an embodiment, where the transmissive parts TP6 are arranged in the first direction DR1 as an example, angles θ16, θ26, θ36, θ46, and θ56 at which vertices closest to the reference line RL are positioned may be different from each other. That is, the transmissive parts TP6 arranged in the first direction DR1 may have shapes obtained through rotation by different tilt angles.

Referring to FIG. 14B, in the light shielding layer LBL6-C according to the comparative embodiment, shapes of all of transmissive parts TPC6 may be the same pentagonal shape. That is, the transmissive parts TP6 (see FIG. 14A) according to an embodiment of the disclosure may be obtained by rotating/tilting the transmissive parts TPC6 according to the comparative embodiment by different tilt angles. In the light shielding layer LBL6-C according to the comparative embodiment, angles θ16c, θ26c, θ36c, θ46c, and θ56c between the transmissive parts arranged in the first row of the reference line RL may be the same as each other, and a tilt angle that is a difference between the angles θ16c, θ26c, θ36c, θ46c, and θ56c may be 0°.

The light source image IM6-C captured through the light shielding layer LBL6-C according to the comparative embodiment shown in FIG. 14B may exhibit a relatively large light splitting phenomenon as compared to the light source image IM6-E captured through the light shielding layer LBL6-E according to an embodiment of the disclosure shown in FIG. 14A. In the display panel according to an embodiment of the disclosure, as the plurality of transmissive parts TP6 having different shapes through tilting at different angles are formed in the light shielding layer LBL6-C, the light splitting phenomenon may be alleviated as compared to the light shielding layer LBL6-C having the transmissive parts TPC6 having the same shape. According to an embodiment of the disclosure, the phenomenon in which the light is diffracted in a specific direction may be alleviated by rotating the transmissive parts uniformly arranged in the same shape. Accordingly, the light leakage phenomenon or the light splitting phenomenon in a specific direction may be reduced, and display characteristics in the first area A1 may be improved.

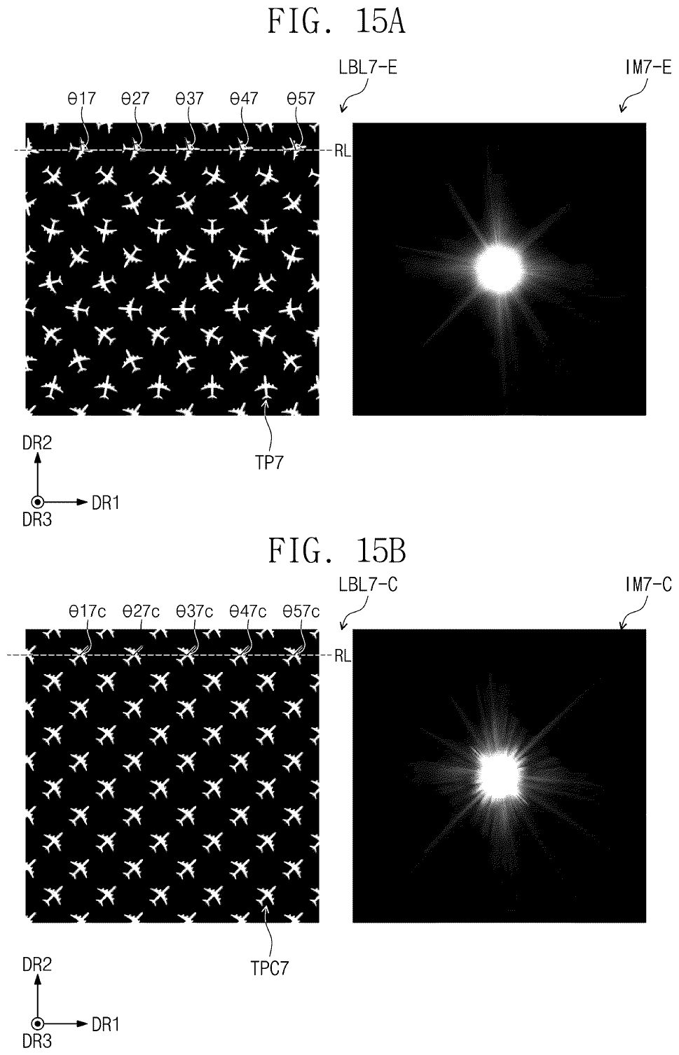

FIGS. 15A and 15B are views illustrating the light shielding layer of the first area and the light source image captured through the first area. FIG. 15A illustrates a light shielding layer LBL7-E and a light source image IM7-E according to an embodiment of the disclosure, and FIG. 15B illustrates a light shielding layer LBL7-C and a light source image IM7-C according to a comparative embodiment. Hereinafter, any repetitive detailed description of the same or like elements as those described above will be omitted.

Referring to FIG. 15A, in the light shielding layer LBL7-E according to an embodiment of the disclosure, transmissive parts TP7 may include N different irregular shapes. It is illustrated in an embodiment that the irregular shape is an airplane shape. The shapes of the transmissive parts TP7 may be shapes obtained by rotating the reference shape by predetermined tilt angles, and the tilt angles may be different from each other. Accordingly, the light shielding layer LBL7-E including the transmissive parts TP7 in the form in which airplane shapes heading in different directions are arranged may be illustrated.

In an embodiment, where the transmissive parts TP7 are arranged in the first direction DR1 as an example, angles θ17, θ27, θ37, θ47, and θ57 at which vertices closest to the reference line RL are positioned may be different from each other. That is, the transmissive parts TP7 arranged in the first direction DR1 may have shapes obtained through rotation by different tilt angles.

Referring to FIG. 15B, in the light shielding layer LBL7-C according to the comparative embodiment, shapes of all of transmissive parts TPC7 may be the same as each other. That is, the transmissive parts TP7 (see FIG. 15A) according to an embodiment of the disclosure may be obtained by rotating/tilting the transmissive parts TPC7 according to the comparative embodiment by different tilt angles. Accordingly, the light shielding layer LBL7-C including the transmissive parts TPC7 in the form in which airplane shapes heading in the same direction are arranged may be illustrated. In the light shielding layer LBL7-C according to the comparative embodiment, angles θ17c, θ27c, θ37c, θ47c, and θ57c between the transmissive parts arranged in the first row of the reference line RL may be the same as each other, and a tilt angle that is a difference between the angles θ17c, θ27c, θ37c, θ47c, and θ57c may be 0°.

The light source image IM7-C captured through the light shielding layer LBL7-C according to the comparative embodiment shown in FIG. 15B may exhibit a relatively large light splitting phenomenon as compared to the light source image IM7-E captured through the light shielding layer LBL7-E according to an embodiment of the disclosure shown in FIG. 15A. In the display panel according to an embodiment of the disclosure, as the plurality of transmissive parts TP7 having different shapes through tilting at different angles are formed in the light shielding layer LBL7-C, the light splitting phenomenon may be alleviated as compared to the light shielding layer LBL7-C having the transmissive parts TPC7 having the same shape. According to an embodiment of the disclosure, the phenomenon in which the light is diffracted in a specific direction may be alleviated by rotating the transmissive parts uniformly arranged in the same shape. Accordingly, the light leakage phenomenon or the light splitting phenomenon in a specific direction may be reduced, and display characteristics in the first area A1 may be improved.

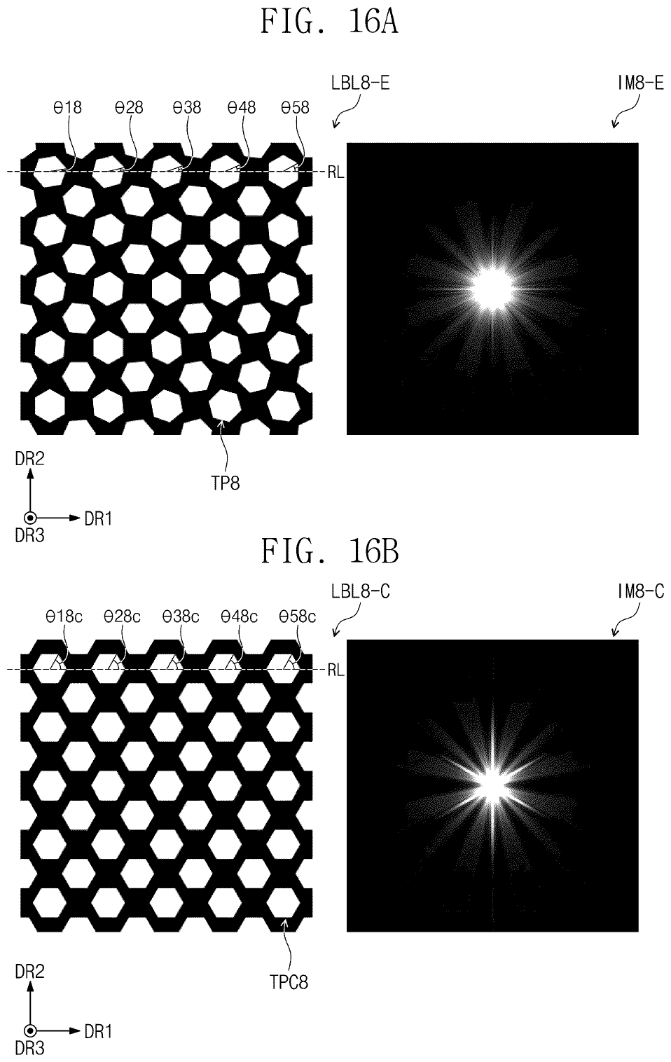

FIGS. 16A and 16B are views illustrating the light shielding layer of the first area and the light source image captured through the first area. FIG. 16A illustrates a light shielding layer LBL8-E and a light source image IM8-E according to an embodiment of the disclosure, and FIG. 16B illustrates a light shielding layer LBL8-C and a light source image IM8-C according to a comparative embodiment. Hereinafter, any repetitive detailed description of the same or like elements as those described above will be omitted.

Referring to FIG. 16A, in the light shielding layer LBL8-E according to an embodiment of the disclosure, transmissive parts TP8 may include N different hexagonal shapes. The shapes of the transmissive parts TP8 may be shapes obtained by rotating the reference shape by predetermined tilt angles, and the tilt angles may be different from each other.

In an embodiment, where the transmissive parts TP8 are arranged in the first direction DR1 as an example, angles θ18, θ28, θ38, θ48, and θ58 at which vertices closest to the reference line RL are positioned may be different from each other. That is, the transmissive parts TP8 arranged in the first direction DR1 may have shapes obtained through rotation by different tilt angles.

Referring to FIG. 16B, in the light shielding layer LBL8-C according to the comparative embodiment, shapes of all of transmissive parts TPC8 may be the same pentagonal shape. That is, the transmissive parts TP8 (see FIG. 16A) according to an embodiment of the disclosure may be obtained by rotating/tilting the transmissive parts TPC8 according to the comparative embodiment by different tilt angles. In the light shielding layer LBL8-C according to the comparative embodiment, angles θ18c, θ28c, θ38c, θ48c, and θ58c between the transmissive parts arranged in the first row of the reference line RL may be the same as each other, and a tilt angle that is a difference between the angles θ18c, θ28c, θ38c, θ48c, and θ58c may be 0°.

The light source image IM8-C captured through the light shielding layer LBL8-C according to the comparative embodiment shown in FIG. 16B may exhibit a relatively large light splitting phenomenon as compared to the light source image IM8-E captured through the light shielding layer LBL8-E according to an embodiment of the disclosure shown in FIG. 16A. In the display panel according to an embodiment of the disclosure, as the plurality of transmissive parts TP8 having different shapes through tilting at different angles are formed in the light shielding layer LBL8-C, the light splitting phenomenon may be alleviated as compared to the light shielding layer LBL8-C having the transmissive parts TPC8 having the same shape. According to an embodiment of the disclosure, the phenomenon in which the light is diffracted in a specific direction may be alleviated by rotating the transmissive parts uniformly arranged in the same shape. Accordingly, the light leakage phenomenon or the light splitting phenomenon in a specific direction may be reduced, and display characteristics in the first area A1 may be improved.

According to an embodiment of the disclosure, transmittance of a transmissive area may be improved, and image distortion of a light passing through the transmissive area may be reduced. Thus, an electronic device may provide a captured image having improved quality.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An electronic device comprising:
a display panel including a first area including a transmissive area and a second area spaced apart from the transmissive area on a plane and adjacent to the first area, wherein the display panel includes:
a light shielding layer in which a plurality of first openings is defined in the first area, wherein each of the first openings defines the transmissive area;
a plurality of light emitting elements, each of which includes a light emitting layer spaced apart from the first openings; and
a plurality of driving units, each of which is connected to a corresponding one of the light emitting elements, is spaced apart from the first openings on a plane, and includes a transistor,
wherein each of the first openings has one of N different shapes, wherein N is a natural number greater than or equal to two,
wherein the N shapes include one reference shape and N−1 tilted shapes,
wherein the tilted shapes correspond to shapes obtained by rotating the reference shape by predetermined tilt angles, and
wherein the tilt angles of the tilted shapes are different from each other.

2. The electronic device of claim 1, wherein, a number of the first openings arranged in the transmissive area is M, wherein N is greater than three and M is a natural number greater than N.

3. The electronic device of claim 2, wherein the reference shape is not a circular shape.

4. The electronic device of claim 3, wherein the reference shape has L vertices, wherein L is a natural number.

5. The electronic device of claim 4, wherein one of the tilt angles is greater than 360/N and less than 360/M.

6. The electronic device of claim 3, wherein the reference shape has a polygonal shape.

7. The electronic device of claim 3, wherein the reference shape has an irregular shape.

8. The electronic device of claim 1, wherein a difference between a number of the first openings having a same shape and a number of the first openings having another same shape within the first area is 1 or less.

9. The electronic device of claim 1, wherein the display panel further includes:
a lower light shielding layer including a conductive material and overlapping the transistors;
a pixel defining layer, in which second openings are defined, wherein each of the second openings has a different shapes from the first openings and overlaps a corresponding one of the light emitting layers; and
a black matrix in which third openings overlapping the second openings are defined, and
wherein the light shielding layer includes at least one selected from the lower light shielding layer, the pixel defining layer, and the black matrix.

10. The electronic device of claim 9, wherein the light shielding layer has a black color.

11. The electronic device of claim 9, wherein the light shielding layer includes a light absorbing material.

12. The electronic device of claim 1,
wherein the light emitting layer of each of the light emitting elements in the first area is spaced apart from the transmissive area and overlaps the light shielding layer.

13. The electronic device of claim 1, wherein an area of the light emitting layer in the first area and an area of the light emitting layer in the second area are different from each other.

14. The electronic device of claim 1, wherein the tilted shapes are arranged in a way such that the tilt angles thereof are increased in one direction.

15. The electronic device of claim 1, wherein the tilted shapes are arranged randomly.

16. An electronic device comprising:
a display panel including a first area including a transmissive area and a second area spaced apart from the transmissive area on a plane and adjacent to the first area,
wherein the display panel includes:
a light shielding layer in which a plurality of first openings is defined in the first area, wherein each of the first openings defines the transmissive area;
a plurality of light emitting elements arranged in a plurality of second openings, respectively, wherein the second openings are different from the first openings; and
a plurality of driving units, each of which is connected to a corresponding one of the light emitting elements, is spaced apart from the first openings on a plane, and includes a transistor,
wherein each of the first openings has one of N different shapes, wherein N is a natural number greater than or equal to two,
wherein the N shapes include one reference shape and N−1 tilted shapes,
wherein the reference shape corresponds to a shape having L vertices, wherein L is a natural number, and
wherein the tilted shapes correspond to shapes obtained by rotating the reference shape by predetermined tilt angles.

17. The electronic device of claim 16, wherein the N shapes have different tilt angles from each other, and
wherein one of the tilt angles is 360/N or less.

18. The electronic device of claim 16, wherein the N shapes are arranged in a direction in which the tilt angles are increased in one direction.

19. The electronic device of claim 16, wherein a difference between a number of the first openings having a same shape and a number of the first openings having another same shape within the first area is 1 or less.

20. An electronic device comprising:
a display panel including a first area including a transmissive area and a second area spaced apart from the transmissive area on a plane and adjacent to the first area; and
an electronic module overlapping the first area, the electronic module including a camera or an optical sensor, and
wherein the display panel includes:
a light shielding layer in which a plurality of first openings is defined in the first area, wherein each of the first openings defines the transmissive area;
a plurality of light emitting elements, each of which includes a light emitting layer spaced apart from the first openings;
a plurality of driving units, each of which is connected to a corresponding one of the light emitting elements, is spaced apart from the first openings on a plane, and includes a transistor, and
wherein each of the first openings has one of N different shapes, wherein N is a natural number greater than or equal to two,
wherein the N shapes include one reference shape and N−1 tilted shapes,
wherein the tilted shapes correspond to shapes obtained by rotating the reference shape by predetermined tilt angles, and
wherein the tilt angles of the tilted shapes are different from each other.

21. The electronic device of claim 20, wherein the N shapes have different tilt angles from each other, and
wherein one of the tilt angles is 360/N or less.

22. The electronic device of claim 20, wherein the N shapes are arranged in a direction in which the tilt angles are increased in one direction.
